(19) United States
(12) Patent Application Publication
(10) Pub. No.: US 2024/0381721 A1
(43) Pub. Date: Nov. 14, 2024

(54) DISPLAY DEVICE

(71) Applicant: Samsung Display Co., Ltd., Yongin-Si (KR)

(72) Inventors: Dong Hoon LEE, Yongin-si (KR); Hae Min KIM, Yongin-si (KR); Young Wan SEO, Yongin-si (KR); Geun Ho LEE, Yongin-si (KR)

(21) Appl. No.: 18/512,015

(22) Filed: Nov. 17, 2023

(30) Foreign Application Priority Data
May 11, 2023 (KR) 10-2023-0060913

(51) Int. Cl. H10K 59/131; H10K 59/124; H10K 59/35; H10K 59/40; H10K 59/88

(52) U.S. Cl. CPC H10K 59/131; H10K 59/124; H10K 59/353; H10K 59/40; H10K 59/88

(57) ABSTRACT

A display device includes a substrate including a main area and a sub-area, the main area including a display area and a non-display area surrounding the display area, and the sub-area including a demultiplexer area and a bending area positioned between the demultiplexer area and the main area, and a circuit layer disposed on the substrate and including pixel circuits arranged at a first pitch in a second direction crossing the first direction, data lines connected to the pixel circuits, and demultiplexer circuits arranged in the demultiplexer area at the first pitch in the second direction and including first switches and second switches. The circuit layer further includes first lines and second lines respectively connected to the first switches and the second switches, and shield lines disposed between adjacent first lines and second lines, respectively.

### CROSS-REFERENCE TO RELATED APPLICATION

This application claims priority to Korean Patent Application No. 10-2023-0060913 filed on May 11, 2023, in the Korean Intellectual Property Office, and all the benefits accruing therefrom under 35 U.S.C. 119, the contents of which in its entirety are herein incorporated by reference.

### BACKGROUND

### 1. Technical Field

Embodiments of the present disclosure relate to a display device.

### 2. Description of the Related Art

The importance of display devices has gradually increased with the development of multimedia. Accordingly, various display devices such as liquid crystal display devices and organic light emitting display devices have been developed.

### SUMMARY

Aspects of the present disclosure provide a display device capable of reducing a non-display area and reducing a resistance deviation of data lines.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a display device includes a substrate including a main area and a sub-area protruding from one side of the main area in a first direction, the main area including a display area in which pixels are arranged and a non-display area surrounding the display area, and the sub-area including a demultiplexer area and a bending area positioned between the demultiplexer area and the main area, and a circuit layer disposed on the substrate and including pixel circuits of the pixels arranged in the display area at a first pitch in a second direction crossing the first direction, data lines connected to the pixel circuits, and demultiplexer circuits arranged in the demultiplexer area at the first pitch in the second direction and including first switches and second switches. The circuit layer further includes first lines connected to the first switches, respectively, and second lines connected to the second switches, respectively, the first lines and the second lines extending from the demultiplexer area to the main area through the bending area and connecting the first switches and the second switches to the data lines, respectively, and shield lines disposed between adjacent first lines and the second lines, respectively.

In an embodiment, the first lines and the second lines may be formed as straight lines extending in the first direction in the demultiplexer area, the bending area, and the main area.

In an embodiment, the sub-area may further include a first line crossing area positioned between the demultiplexer area and the bending area, and a second line crossing area positioned between the bending area and the main area.

In an embodiment, in the demultiplexer area and the main area, the first lines and the second lines may be arranged along the second direction in a first order, and, in the bending area, the first lines and the second lines are arranged along the second direction in a second order different from the first order, and the shield lines may be disposed between adjacent first line groups each including at least two first lines and second line groups each including at least two second lines, respectively.

In an embodiment, in the first line crossing area, some of the first lines and some of the second lines may cross each other and, in the second line crossing area, the some of the first lines and the some of the second lines cross each other such that an arrangement order of the first lines and the second lines is the same as an arrangement order of the first lines and the second lines in the demultiplexer area.

In an embodiment, the first lines, the second lines, and the shield lines may be arranged at uniform intervals along the second direction in the bending area.

In an embodiment, the first switches may be turned on by a first clock signal and the second switches may be turned on by a second clock signal.

In an embodiment, the circuit layer may further include a power line positioned in the main area and the sub-area, and connected to the pixels, and the shield lines may be connected to the power line around the bending area.

In an embodiment, the circuit layer may include a semiconductor layer disposed on the substrate, a first conductive layer disposed on a first insulating layer covering the semiconductor layer, a second conductive layer disposed on a second insulating layer covering the first conductive layer, a third conductive layer disposed on a third insulating layer covering the second conductive layer, a fourth conductive layer disposed on a fourth insulating layer covering the third conductive layer, and a fifth conductive layer disposed on a fifth insulating layer covering the fourth conductive layer.

In an embodiment, the power line may be provided at the fifth conductive layer in a first line crossing area positioned between the bending area and the demultiplexer area and a second line crossing area positioned between the bending area and the main area.

In an embodiment, the shield lines may extend from the bending area to the first line crossing area and the second line crossing area, and each of the shield lines may be provided at the fourth conductive layer in the bending area and may be provided at at least one of the first conductive layer, the second conductive layer, the third conductive layer, and the fourth conductive layer and may be electrically connected to the power line in the first line crossing area and the second line crossing area.

In an embodiment, each of the shield lines may be formed as a multilayer line including a first line layer provided at at least one of the first conductive layer, the second conductive layer, and the third conductive layer and a second line layer provided at the fourth conductive layer, in the first line crossing area and the second line crossing area.

In an embodiment, the first lines and the second lines may be provided at at least one of the first conductive layer, the second conductive layer, the third conductive layer, and the fourth conductive layer in the demultiplexer area, the first line crossing area, the bending area, and the second line crossing area.

In an embodiment, the display area may include a first display area which are positioned in an edge area of the display area in the second direction and in which first data lines and the pixels connected to the first data lines are arranged, and a second display area which neighbors to the first display area in the second direction and overlaps a first demultiplexer area of the demultiplexer area in the first direction and in which second data lines and the pixels connected to the second data lines are arranged.

In an embodiment, the demultiplexer circuits may include first demultiplexer circuits positioned in the first demultiplexer area, some of the first lines and the second lines connected to the first demultiplexer circuits may be connected to the second data lines, and the others of the first lines and the second lines connected to the first demultiplexer circuits may be connected to the first data lines via connection lines passing through a boundary between the first display area and the second display area.

In an embodiment, the first data lines may extend in the first direction in the first display area, the second data lines may extend in the first direction in the second display area, and the connection lines may extend from the first display area to the second display area along the second direction.

In an embodiment, the display area may further include a third display area which neighbors to the second display area in the second direction and overlaps a second demultiplexer area of the demultiplexer area in the first direction and in which third data lines and the pixels connected to the third data lines are arranged.

In an embodiment, the demultiplexer circuits may further include second demultiplexer circuits positioned in the second demultiplexer area and connected to the third data lines through first lines and second lines extending from the second demultiplexer area, and dummy demultiplexer circuits disposed between the second demultiplexer circuits.

In an embodiment, the display device may further include a driving circuit supplying data signals to the demultiplexer circuits. The dummy demultiplexer circuits may be electrically disconnected to the driving circuit.

According to an aspect of the present disclosure, a display device includes a substrate including a main area and a sub-area positioned on one side of the main area, the main area including a display area in which pixels are arranged, and the sub-area including a demultiplexer area and a first line crossing area, a bending area, and a second line crossing area sequentially disposed along a first direction between the demultiplexer area and the main area, and a circuit layer disposed on the substrate and including data lines positioned in the display area and connected to the pixels, demultiplexer circuits positioned in the demultiplexer area and including first switches configured to receive a first clock signal and second switches configured to receive a second clock signal, and a power line positioned in the main area and the sub-area. The circuit layer further includes first lines connecting the first switches to corresponding data lines and second lines connecting the second switches to corresponding data lines, and shield lines disposed between adjacent first lines and second lines, respectively, and connected to the power line, and the first lines and the second lines extend in the first direction in an area other than the first line crossing area and the second line crossing area.

According to embodiments, by arranging demultiplexer circuits at a first pitch corresponding to that of pixel circuits in a demultiplexer area positioned below a bending area, it is possible to form data output lines in a uniform direction and at a uniform length from the demultiplexer area to a display area and/or the periphery of the display area without a substantial fan-out section. Accordingly, it is possible to reduce a non-display area and reduce or minimize resistance and resistance deviations of the data output lines and data lines connected to the data output lines.

In addition, according to embodiments, at least some of the data output lines may cross each other and/or be rearranged around the bending area so that a plurality of data output lines driven by the same clock signal are disposed adjacent to each other in the bending area or the like, and shield lines may be disposed between the data output lines driven by different clock signals. Accordingly, it is possible to prevent or shield coupling between the data output lines to prevent or reduce voltage fluctuations of data signals.

In some embodiments, the shield lines may be formed as multilayer lines. Accordingly, resistance of power lines connected to the shield lines may be reduced to prevent or reduce a source voltage drop and heat generation of the power lines.

In some embodiments, by disposing dummy demultiplexer circuits between second demultiplexer circuits positioned in a second demultiplexer area positioned below a third display area, it is possible to generally uniformly arrange and form the demultiplexer circuits and the data output lines in the demultiplexer area. Accordingly, it is possible to make loads of the demultiplexer circuits and the data output lines uniform and prevent or reduce a voltage deviation of data signals transferred to pixels.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a plan view illustrating the display device of FIG. 1;

FIG. 3 is a cross-sectional view illustrating an embodiment of a cross section taken along line A-A′ of FIG. 2;

FIG. 4 is a plan view illustrating a display panel according to an embodiment;

FIG. 5 is a plan view illustrating the display panel and power lines according to an embodiment;

FIG. 6 is a circuit diagram illustrating a pixel according to an embodiment;

FIG. 7 is a circuit diagram illustrating a pixel according to an embodiment;

FIG. 8 is a cross-sectional view illustrating the display panel according to an embodiment;

FIG. 9 is a circuit diagram illustrating a demultiplexer unit and lines around the demultiplexer unit according to an embodiment;

FIG. 10 is a plan view illustrating area C of FIG. 9;

FIG. 11 is a cross-sectional view illustrating an embodiment of a cross section taken along line D-D′ of FIG. 10;

FIG. 12 is a cross-sectional view illustrating an embodiment of a cross section taken along line E-E′ of FIG. 10;

FIG. 13 is a cross-sectional view illustrating an embodiment of a cross section taken along line F-F′ of FIG. 10;

FIG. 14 is a plan view illustrating area C of FIG. 9;

FIG. 15 is a cross-sectional view illustrating an embodiment of a cross section taken along line G-G′ of FIG. 14;

FIG. 16 is a plan view illustrating a first demultiplexer area according to an embodiment; and

FIG. 17 is a plan view illustrating a second demultiplexer area according to an embodiment.

### DETAILED DESCRIPTION OF THE EMBODIMENTS

The present inventive concept will now be described more fully hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present inventive concept. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

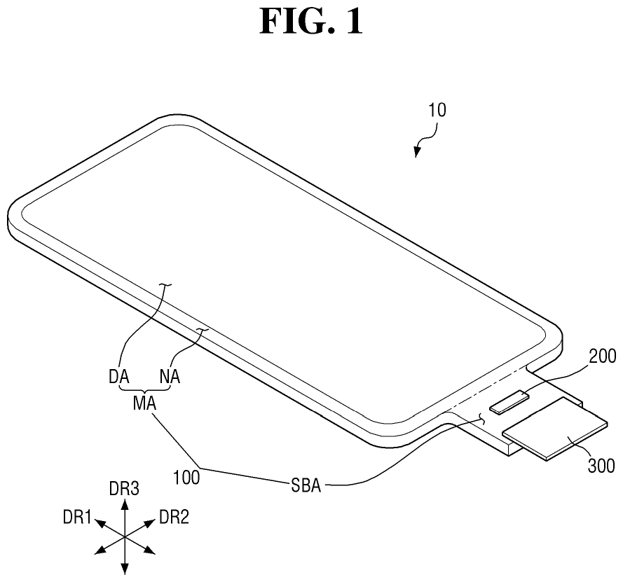

FIG. 1 is a perspective view illustrating a display device 10 according to an embodiment.

Referring to FIG. 1, a display device 10 is a device that displays a moving image or a still image, and may be used as a display screen of various products such as televisions, laptop computers, monitors, billboards, and the Internet of Things (IoT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

The display device 10 may be a light emitting display device such as an organic light emitting display device including organic light emitting diodes, a quantum dot light emitting display device including quantum dot light emitting layers, an inorganic light emitting display device including inorganic semiconductors, or a micro light emitting display device using micro or nano light emitting diodes (micro LEDs or nano LEDs). Hereinafter, an embodiment in which the display device 10 is an organic light emitting display device has been described, but a type of the display device 10 is not limited thereto.

In an embodiment, the display device 10 may be formed to be flat. For example, the display device 10 may be formed to be substantially flat on a plane defined by a first direction DR1 and a second direction DR2 and may have a predetermined thickness (or height) in a third direction DR3. In another embodiment, the display device 10 may include curved portions in at least a portion thereof including an edge area or the like. In addition, the display device 10 may be flexibly formed to be curved, bent, folded, or rolled.

In an embodiment, based on an image display surface of the display device 10, the first direction DR1 may be a longitudinal direction, a column direction, or a vertical direction, and the second direction DR2 is a direction crossing the first direction DR1 and may be, for example, a transverse direction, a row direction, or a horizontal direction. The third direction DR3 may be a thickness direction or a height direction of the display device 10.

The display device 10 may include a display panel 100, a driving circuit 200, and a circuit board 300.

The display panel 100 may include a main area MA including a display area DA on which an image is displayed and a sub-area SBA positioned on one side of the main area MA.

The main area MA may include the display area DA and a non-display area NA positioned around the display area DA.

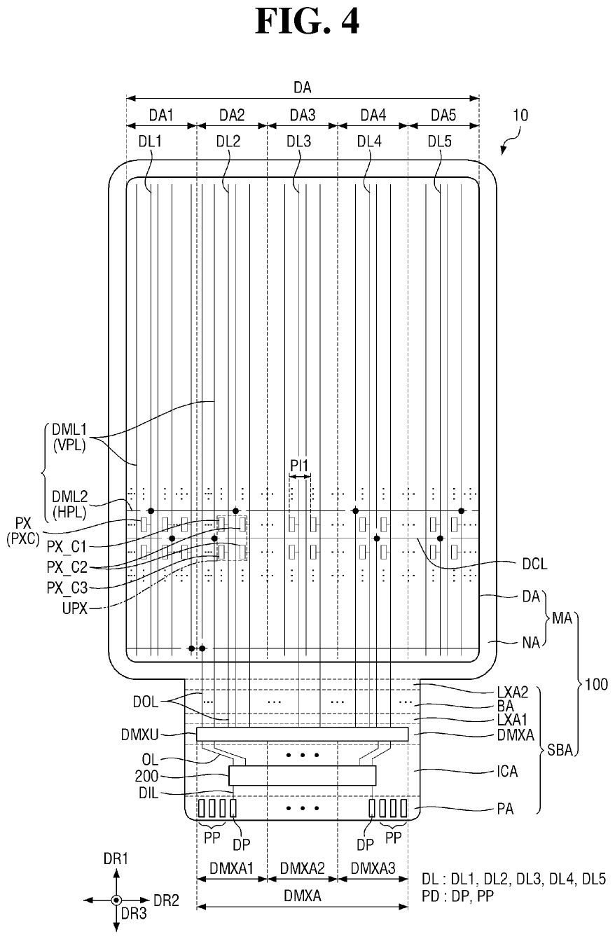

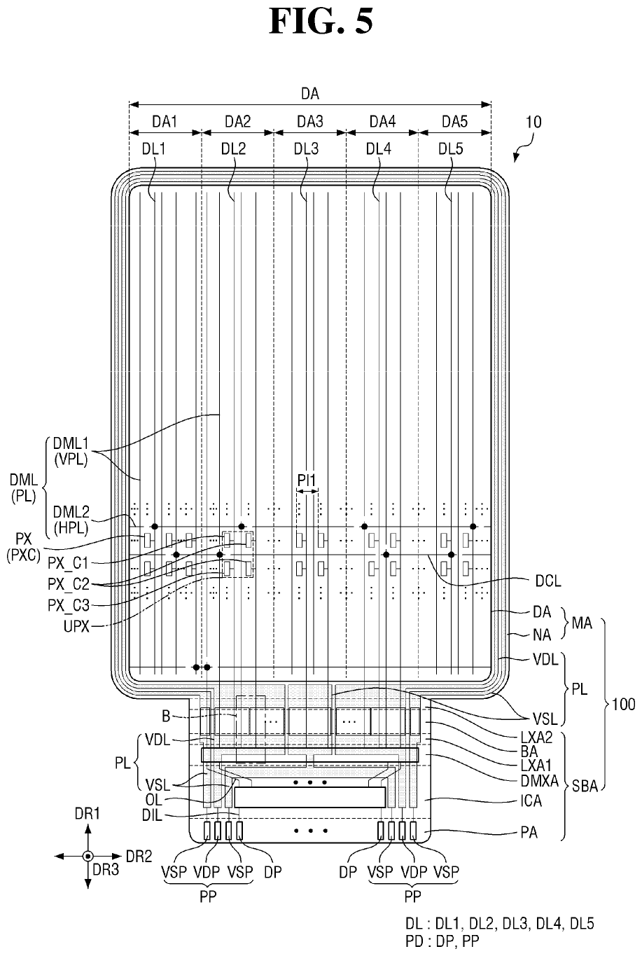

The display area DA is an area in which pixels (e.g., pixels PX of FIGS. 4 and 5) are arranged, and may be an area in which an image is displayed by the pixels PX. In an embodiment, the display area DA may be further provided with sensing patterns for sensing a touch input, for example, touch electrodes, and may include a sensing area sensing the touch input using the sensing patterns.

The non-display area NA may be disposed immediately around the display area DA. The non-display area NA may surround the display area DA. In an embodiment, an embedded circuit may be disposed in the non-display area NA. For example, an embedded circuit including a scan driving circuit or the like may be disposed in the non-display area NA positioned on one side (e.g., the left side or the right side) or both sides of the display area DA.

The sub-area SBA may protrude from one side of the main area MA in the first direction DR1. For example, the sub-area SBA may protrude from a lower end of the main area MA in the first direction DR1, and may have a width smaller than that of the main area MA in the second direction DR2.

In an embodiment, the driving circuit 200 (e.g., a display driving circuit) may be mounted in the sub-area SBA. In addition, the circuit board 300 may be disposed on a portion of the sub-area SBA (e.g., a pad area PA of FIGS. 4 and 5).

Lines connected to the pixels of the display area DA and/or the embedded circuit, the driving circuit 200, and the circuit board 300 may be disposed in the sub-area SBA. In describing embodiments, the term “connection” may include the meaning of an electrical connection and/or a physical connection.

The driving circuit 200 may include a data driving circuit for driving the pixels. In an embodiment, the driving circuit 200 may be provided as an integrated circuit (IC) and mounted in the sub-area SBA. In another embodiment, the driving circuit 200 may be provided on the circuit board 300 on the sub-area SBA or may be provided on another circuit board connected to the display panel 100 through the circuit board 300.

The circuit board 300 may be disposed on a portion of the sub-area SBA. For example, the circuit board 300 may be bonded onto pads positioned at one end of the sub-area SBA, and may supply or transfer source voltages and driving signals for driving the display panel 100 to the display panel 100. For example, the circuit board 300 may supply input image data (e.g., digital image data), driving signals including timing signals, and driving voltages to the display panel 100. The circuit board 300 may be a flexible printed circuit board (FPCB), a printed circuit board (PCB), or a flexible film such as a chip on film (COF), but is not limited thereto.

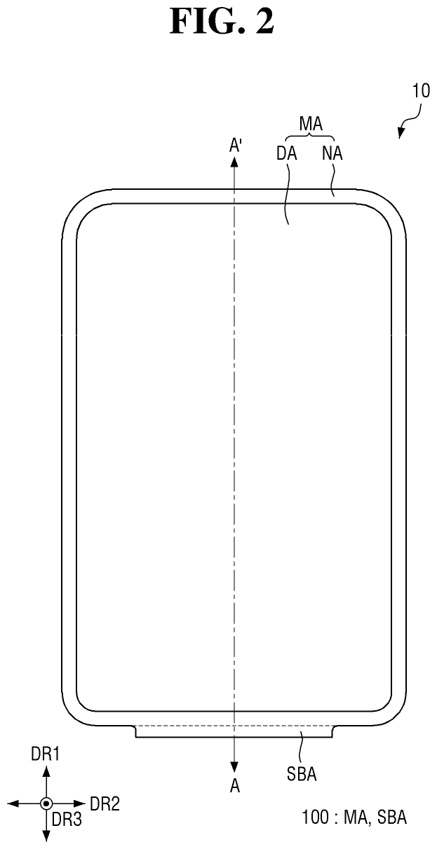

FIG. 2 is a plan view illustrating the display device 10 of FIG. 1. FIG. 1 illustrates a state in which the display device 10 is not bent, and FIG. 2 illustrates a state in which the display device 10 is bent in the sub-area SBA. For example, FIG. 1 illustrates a state in which the sub-area SBA is unbent in parallel with the main area MA, and FIG. 2 illustrates a state in which a portion of the sub-area SBA is bent.

Referring to FIGS. 1 and 2, the display area DA may be formed in a substantially rectangular shape, in a plan view, including long sides in the first direction DR1 and short sides in the second direction DR2. A corner portion where the long side and the short side of the display area DA meet may be rounded or have right-angled. The shape of the display area DA in a plan view is not limited to the rectangular shape, and may be other polygonal shapes, a circular shape, an elliptical shape, or the like.

The display area DA may occupy most of the main area MA. The display area DA may be disposed at the center of the main area MA.

The non-display area NA may be positioned at an edge of the main area MA. The non-display area NA may be in contact with the sub-area SBA.

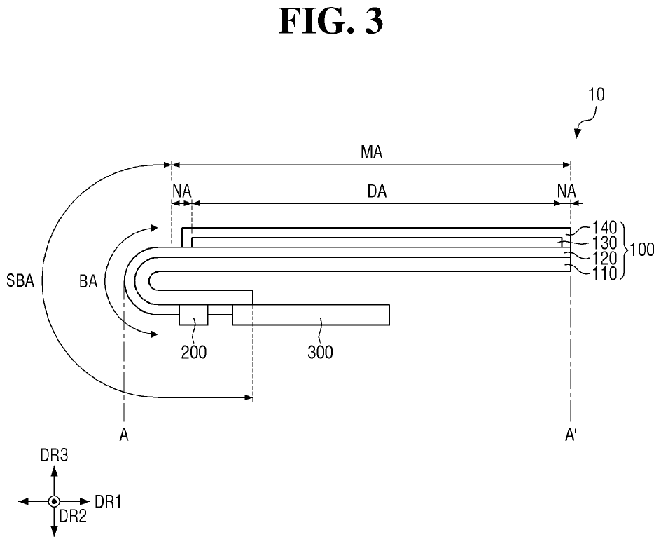

FIG. 3 is a cross-sectional view illustrating an embodiment of a cross section taken along line A-A′ of FIG. 2.

Referring to FIGS. 1 to 3, the display panel 100 may include a substrate 110 including a main area MA and a sub-area SBA, a circuit layer 120 disposed on the substrate 110, a light emitting element layer 130 disposed on the circuit layer 120, and an encapsulation layer 140 disposed on light emitting element layer 130. In an embodiment, the display device 10 may further include additional components disposed on the display panel 100. For example, the display device 10 further includes at least one of a sensor layer (e.g., a touch sensor layer), a polarization layer, a color filter layer, and a protective layer (e.g., a window) disposed on the encapsulation layer 140. Each of the sensor layer, the polarization layer, the color filter layer, and/or the protective layer may be manufactured integrally with the display panel 100 or may be manufactured separately from the display panel 100 and attached to the display panel 100 via an adhesive layer or the like.

The substrate 110 may include an insulating material such as a polymer resin. For example, the substrate 110 may be made of polyimide or other insulating materials. The substrate 110 may be a flexible substrate that may be deformed, for example, bent, folded, and rolled. Alternatively, the substrate 110 may include an insulating material such as glass.

The circuit layer 120 may include circuit elements (e.g., transistors and a capacitor) constituting a pixel circuit of each of the pixels and lines connected to the pixels. In an embodiment, the circuit layer 120 may further include circuit elements constituting the embedded circuit such as the scan driving circuit and lines connected to the embedded circuit.

The light emitting element layer 130 may include light emitting elements provided in emission areas of the pixels. For example, each pixel may include at least one light emitting element and a pixel circuit connected to the light emitting element. Each pixel may be positioned in each pixel area including the emission area in which the light emitting element is disposed and a pixel circuit area in which the pixel circuit is disposed. The emission area and the pixel circuit area of each pixel may overlap each other, but are not limited thereto.

The encapsulation layer 140 may cover the light emitting element layer 130 and extend into the non-display area NA to be in contact with the circuit layer 120. In an embodiment, the encapsulation layer 140 may have a multilayer structure in which at least two inorganic films and at least one organic film are alternately stacked.

The display panel 100 may be bent in a bending area BA. The bending area BA may be a portion of the sub-area SBA and may be spaced apart from the main area MA. For example, the substrate 110 and the circuit layer 120 may be bent in the bending area BA corresponding to a partial section of the sub-area SBA.

FIG. 4 is a plan view illustrating a display panel 100 according to an embodiment.

FIG. 4 illustrates a state in which the display panel 100 is not bent.

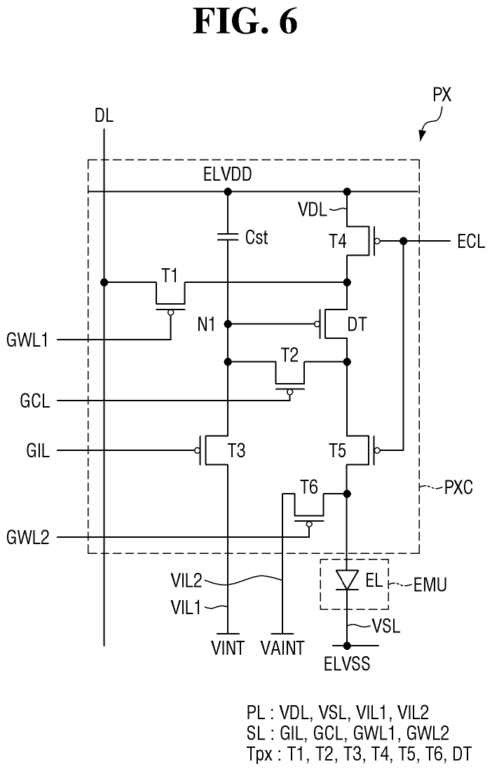

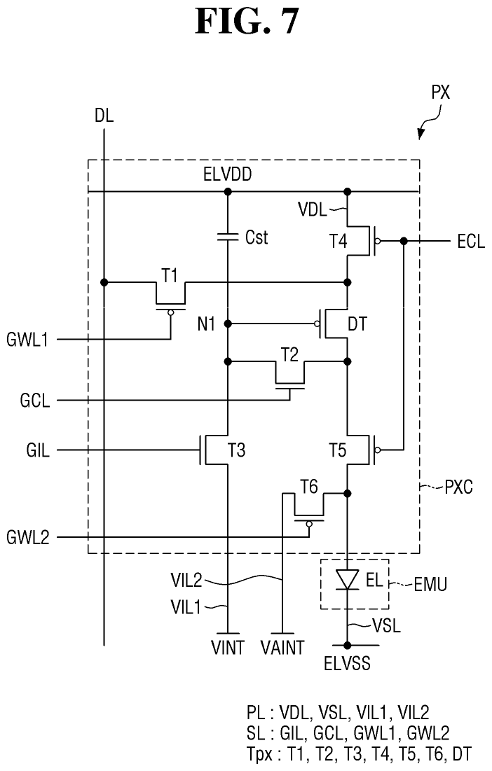

Referring to FIG. 4, the display area DA may include data lines DL and pixels PX connected to the data lines DL. The display area DA may further include scan lines (e.g., scan lines SL of FIGS. 6 and 7) and power lines (e.g., power lines PL of FIGS. 6 and 7) connected to the pixels PX.

The data lines DL may be provided or disposed in respective pixel columns. Each of the data lines DL may be connected to pixels PX positioned in a corresponding pixel column.

The pixels PX may be arranged in respective pixel rows and pixel columns. The pixels PX may emit light with luminance corresponding to data signals (e.g., data voltages) supplied from the respective data lines DL.

In FIG. 4, an arrangement structure and positions of the pixels PX have been illustrated based on a pixel circuit PXC of each of the pixels PX. The pixel circuits PXC of the pixels PX may be arranged in the display area DA at a first pitch PIl in the second direction DR2. The data lines DL may be arranged in the display area DA at a pitch corresponding to that of the pixel circuits PXC. For example, the data lines DL may also be uniformly arranged in the display area DA at the first pitch PIl in the second direction DR2.

The pixels PX may include at least two color pixels PX emitting light of different colors. For example, the pixels PX may include first color pixels PX_C1 emitting light of a first color (e.g., red light), second color pixels PX_C2 emitting light of a second color (e.g., green light), and third color pixels PX_C3 emitting light of a third color (e.g., blue light).

At least one first color pixel PX_C1, at least one second color pixel PX_C2, and at least one third color pixel PX_C3 adjacent to each other may constitute a unit pixel UPX. For example, one first color pixel PX_C1, two second color pixels PX_C2, and one third color pixel PX_C3 adjacent to each other may constitute one unit pixel UPX. Each unit pixel UPX may emit light of various colors including white light by mixing colors of light emitted from the pixels PX constituting each unit pixel UPX. In an embodiment, the first color pixels PX_C1 and the third color pixels PX_C3 may be alternately arranged in the first direction DR1 and/or the second direction DR2, and the second color pixels PX_C2 may be continuously and/or sequentially arranged in the first direction DR1. Types, shapes, arrangement structures, and the like of the pixels PX may be variously changed according to embodiments. In addition, types, the number, ratios, arrangement structures, and the like of the pixels PX constituting each unit pixel UPX may also be variously changed according to embodiments.

The display area DA may be divided or partitioned into sub-areas corresponding to different sections along the second direction DR2. For example, the display area DA may include a first display area DA1 disposed at one edge (e.g., a left edge) of the display area DA, a second display area DA2 disposed adjacent to the first display area DA1, a third display area DA3 disposed adjacent to second display area DA2, based on the second direction DR2. For example, the display area DA may include a first display area DA1, a second display area DA2, and a third display area DA3 that are sequentially disposed along the second direction DR2. The second display area DA2 and the third display area DA3 may be areas corresponding to the sub-area SBA in the first direction DR1. For example, the second display area DA2 may be disposed in an area corresponding to a first demultiplexer area DMXA1 which is disposed in the sub-area SBA in the first direction DR1, and the third display area DA3 may be disposed in an area corresponding to a second demultiplexer area DMXA2 which is disposed in the sub-area SBA in the first direction DR1. Demultiplexer circuits (also referred to as “first demultiplexer circuits”) for supplying respective data signals to first data lines DL1 and second data lines DL2 may be disposed in the first demultiplexer area DMXA1, and demultiplexer circuits (also referred to as “second demultiplexer circuits”) for supplying respective data signals to third data lines DL3 may be disposed in the second demultiplexer area DMXA2. The first display area DA1 is an area that is not disposed to overlap the sub-area SBA in the first direction DR1, and may protrude from the sub-area SBA along the second direction.

In an embodiment, the third display area DA3 may be positioned at the center of the display area DA. In addition, the display area DA may further include a fourth display area DA4 and a fifth display area DA5 facing the first display area DA1 and the second display area DA2 with the third display area DA3 interposed therebetween. For example, the display area DA may include a first display area DA1, a second display area DA2, a third display area DA3, a fourth display area DA4, and a fifth display area DA5 that are sequentially disposed along the second direction DR2. The fourth display area DA4 may face the second display area DA2 with the third display area DA3 disposed therebetween. The fifth display area DA5 may face the first display area DA1 with the second, third, and fourth display areas DA2, DA3, and DA4 interposed therebetween. The second display area DA2, the third display area DA3, and the fourth display area DA4 may be areas corresponding to the sub-area SBA in the first direction DR1. For example, the fourth display area DA4 may be disposed in an area corresponding to a third demultiplexer area DMXA3 which is disposed in the sub-area SBA in the first direction DR1. Demultiplexer circuits (also referred to as “third demultiplexer circuits”) for supplying respective data signals to fourth data lines DL4 and fifth data lines DL5 may be disposed in the third demultiplexer area DMXA3. The first display area DA1 and the fifth display area DA5 are areas that are disposed not to overlap the sub-area SBA in the first direction DR1, and may protrude from the sub-area SBA along the second direction.

In the first display area DA1, the first data lines DL1 provided in respective pixel columns and pixels PX (also referred to as “first pixels”) connected to the first data lines DL1 may be arranged. Each of the first data lines DL1 may extend in the first direction DR1 in the first display area DA1 and be connected to pixels PX positioned in a corresponding pixel column.

In the second display area DA2, the second data lines DL2 provided in respective pixel columns and pixels PX (also referred to as “second pixels”) connected to the second data lines DL2 may be arranged. Each of the second data lines DL2 may extend in the first direction DR1 in the second display area DA2 and be connected to pixels PX positioned in a corresponding pixel column.

In the third display area DA3, the third data lines DL3 provided in respective pixel columns and pixels PX (also referred to as “third pixels”) connected to the third data lines DL3 may be arranged. Each of the third data lines DL3 may extend in the first direction DR1 in the third display area DA3 and be connected to pixels PX positioned in a corresponding pixel column.

In the fourth display area DA4, the fourth data lines DL4 provided in respective pixel columns and pixels PX (also referred to as “fourth pixels”) connected to the fourth data lines DL4 may be arranged. Each of the fourth data lines DL4 may extend in the first direction DR1 in the fourth display area DA4 and be connected to pixels PX positioned in a corresponding pixel column.

In the fifth display area DA5, the fifth data lines DL5 provided in respective pixel columns and pixels PX (also referred to as “fifth pixels”) connected to the fifth data lines DL5 may be arranged. Each of the fifth data lines DL5 may extend in the first direction DR1 in the fifth display area DA5 and be connected to pixels PX positioned in a corresponding pixel column.

Connection lines DCL (also referred to as “data connection lines”) extending in the second direction DR2 may be further disposed in the display area DA. For example, connection lines DCL connecting the first data lines DL1 and the fifth data lines DL5 to data output lines DOL of a demultiplexer unit DMXU through the second display area DA2 and the fourth display area DA4, respectively, may be further disposed in the display area DA.

One end of each of the connection lines DCL connected to the first data lines DL1 may be connected to one first data line DL1 positioned in the first display area DA1, and the other end of each of the connection lines DCL connected to the first data lines DL1 may be connected to one data output line DOL disposed in the second display area DA2. The connection lines DCL connected to the first data lines DL1 may pass through a boundary between the first display area DA1 and the second display area DA2. For example, each of the connection lines DCL connected to the first data lines DL1 may extend from the first display area DA1 to the second display area DA2 along the second direction DR2.

One end of each of the connection lines DCL connected to the fifth data lines DL5 may be connected to one fifth data line DL5 positioned in the fifth display area DA5, and the other end of each of the connection lines DCL connected to the fifth data lines DL5 may be connected to one data output line DOL disposed in the fourth display area DA4. The connection lines DCL connected to the fifth data lines DL5 may pass through a boundary between the fourth display area DA2 and the fifth display area DA5. For example, each of the connection lines DCL connected to the fifth data lines DL5 may extend from the fourth display area DA4 to the fifth display area DA5 along the second direction DR2.

In an embodiment, dummy lines DML separated from the data lines DL may be further disposed in the display area DA. The dummy lines DML may include first dummy lines DML1 extending in the first direction DR1 and second dummy lines DML2 extending in the second direction DR2.

At least some of the dummy lines DML may be utilized as power lines PL. For example, each of the first dummy lines DML1 may be utilized as a vertical power line VPL connected to a power line PL supplying any one type of source voltage to constitute a portion of the power line PL. In an embodiment, some of the first dummy lines DML1 may be connected to a first power line (e.g., a first power line VDL of FIG. 5) supplying a first source voltage and the others of the first dummy lines DML1 may be connected to a second power line (e.g., a second power line VSL of FIG. 5) supplying a second source voltage, but a utilization example of the first dummy lines DML1 is not limited thereto. For example, at least some of the first dummy lines DML1 may be utilized as other types of lines. Similarly, each of the second dummy lines DML2 may be utilized as a horizontal power line HPL connected to a power line PL supplying any one type of source voltage to constitute a portion of the power line PL. In an embodiment, some of the second dummy lines DML2 may be connected to the first power line (e.g., the first power line VDL of FIG. 5) supplying the first source voltage and the others of the second dummy lines DML2 may be connected to the second power line (e.g., the second power line VSL of FIG. 5) supplying the second source voltage, but a utilization example of the second dummy lines DML2 is not limited thereto. For example, at least some of the second dummy lines DML2 may be utilized as other types of lines.

The sub-area SBA may include a pad area PA, a demultiplexer area DMXA, and a bending area BA. In an embodiment, the sub-area SBA may further include a first line crossing area LXA1 and a second line crossing area LXA2 positioned around the bending area BA. The sub-area SBA may further include a driving circuit mounting area ICA in which the driving circuit 200 and the like are mounted on the sub-area SBA.

The pad area PA may be positioned in a portion of the sub-area SBA (e.g., a lower edge area). The pad area PA may include power pads PP and signal pads for connecting the display panel 100 to the circuit board 300 and the like. Source voltages for driving the pixels PX and/or the driving circuit 200 may be supplied to the power pads PP. The signal pads may include data pads DP connected to the driving circuit 200 (the demultiplexer unit DMXU when the driving circuit 200 is mounted outside the display panel 100) through data input lines DIL. The signal pads may further include signal pads connected to the demultiplexer unit DMXU (e.g., pads for supplying clock signals to the demultiplexer unit DMXU), and the like. When the display panel 100 includes the embedded circuit such as the scan driving circuit, the pad area PA may further include pads to which source voltages and driving signals for driving the embedded circuit are applied.

The driving circuit mounting area ICA may be positioned between the pad area PA and the demultiplexer area DMXA. The driving circuit 200 may be mounted in the driving circuit mounting area ICA. The driving circuit 200 may be connected to the data pads DP through the data input lines DIL, and be connected to the demultiplexer unit DMXU through output lines OL. The driving circuit 200 may generate data signals corresponding to image data (e.g., data voltages corresponding to the image data) input through the data pads DP, and supply the generated data signals to the demultiplexer unit DMXU through the output lines OL.

The demultiplexer area DMXA may be positioned between the driving circuit mounting area ICA (or the pad area PA) and the bending area BA. For example, the demultiplexer area DMXA may be positioned below the bending area BA in the first direction DR1. The demultiplexer unit DMXU including demultiplexer circuits connected to the output lines OL of the driving circuit 200 may be disposed and/or formed in the demultiplexer area DMXA.

The demultiplexer unit DMXU may output data signals (e.g., data voltages of each of the data signals) input from the driving circuit 200 in response to the clock signals to the data output lines DOL. The data output lines DOL may be connected and/or formed between the demultiplexer circuits disposed in the demultiplexer unit DMXU and the respective data lines DL. The data signals output from the demultiplexer unit DMXU may be transferred to the respective data lines DL through the respective data output lines DOL.

In describing an embodiment, the data output lines DOL and the data lines DL have been described as separate elements, but embodiments are not limited thereto. For example, at least some of the data output lines DOL may be portions of respective data lines DL connected thereto.

In an embodiment, some of the data output lines DOL may be directly connected to corresponding data lines DL in or outside of the display area DA. For example, the data output lines DOL for supplying corresponding data signals to the pixels PX of the second display area DA2, the third display area DA3, and the fourth display area DA4 may be formed integrally or non-integrally with the respective second data lines DL2, third data lines DL3, and fourth data lines DL4, and may be directly connected to the respective second data lines DL2, third data lines DL3, and fourth data lines DL4 without separate connection lines.

The others of the data output lines DOL may be connected to corresponding data lines DL through the respective connection lines DCL provided in the display area DA. For example, the data output lines DOL for supplying corresponding data signals to the pixels PX of the first display area DA1 and the fifth display area DA5 may be formed integrally or non-integrally with the respective first data lines DL1 and fifth data lines DL5, and may be connected to the respective first data lines DL1 and fifth data lines DL5 via the respective connection lines DCL.

The bending area BA may be positioned between the demultiplexer area DMXA and the main area MA. The display panel 100 is bent in the bending area BA, such that a portion of the sub-area SBA may be positioned behind the main area MA.

The first line crossing area LXA1 may be positioned between the demultiplexer area DMXA and the bending area BA. The second line crossing area LXA2 may be positioned between the bending area BA and the main area MA. The first line crossing area LXA1 and the second line crossing area LXA2 may be sections in which at least some of the data output lines DOL cross each other, such that an arrangement order of some of the data output lines DOL is changed.

For example, in the first line crossing area LXA1 and the second line crossing area LXA2, an arrangement order of some of the data output lines DOL may be changed so that at least two data output lines DOL simultaneously receiving the data signals in response to the same clock signals are disposed adjacent to each other in the bending area BA or the like, and may be restored to an original order after the bending area BA. In an embodiment, the first line crossing area LXA1 may be a line bundling area (or a line grouping area) in which the data output lines DOL are grouped and bundled so that the data output lines DOL receiving the data signals in response to the same clock signals are disposed adjacent to each other, and the second line crossing area LXA2 may be a line bundling release area (or a line grouping release area) in which the data output lines DOL are rearranged in the original order.

In an embodiment, the data output lines DOL may be formed as straight lines extending substantially in the first direction DR1. For example, the data output lines DOL may be straight lines extending in the first direction DR1 in the demultiplexer area DMXA, the bending area BA, and the main area MA excluding the first line crossing area LXA1 and the second line crossing area LXA2, which are relatively short sections.

For example, in an embodiment, the demultiplexer unit DMXU may be disposed below the bending area BA, and the data output lines DOL may be connected and/or formed as straight lines from the demultiplexer area DMXA to the display area DA (or the non-display area NA positioned immediately around the display area DA) without a substantial fan-out section. As an example, the data output lines DOL may extend in substantially the same direction and have a uniform length (e.g., a length corresponding to a straight line of the shortest distance from the demultiplexer area DMXA to the display area DA). Accordingly, the non-display area NA may be reduced, and resistance and resistance deviations of the data output lines DOL and the data lines DL connected to the data output lines DOL may be prevented, reduced, or minimized. In addition, since the data output lines DOL generally extend uniformly in the first direction DR1, an interval between the data output lines DOL may be increased as compared with an arrangement of a fan-out form in which at least some of the data output lines DOL are obliquely disposed in the non-display area NA or the like having substantially the same area. Accordingly, parasitic capacitance between the data output lines DOL may be reduced, and noise due to coupling between the data output lines DOL may be prevented or reduced. In addition, when the data output lines DOL are arranged in the fan-out form, a width of the non-display area NA should be sufficiently secured in the first direction DR1 or the like, but in an embodiment, the data output lines DOL uniformly extend in the first direction DR1 in the non-display area NA or the like, and thus, it is not substantially necessary to secure a space required for a fan-out arrangement. Accordingly, the non-display area NA may be reduced or the non-display area NA may be utilized more efficiently.

FIG. 5 is a plan view illustrating the display panel 100 and power lines PL according to an embodiment. For example, FIG. 5 illustrates an embodiment of a first power line VDL and a second power line VSL provided in the display panel 100 of FIG. 4. Only the first power line VDL and the second power line VSL positioned in the non-display area NA of the main area MA and the sub-area SBA have been illustrated in FIG. 5, but the first power line VDL and the second power line VSL may also be formed inside the display area DA and connected to the pixels PX.

Referring to FIG. 5, the power line PL may include at least one first power line VDL and at least one second power line VSL. Depending on a structure of the pixels PX, the display panel 100 may further include at least one power line supplying an additional source voltage.

The first power line VDL may be formed between at least one first power pad VDP provided in the pad area PA and the display area DA. In an embodiment, the first power line VDL may be formed in the non-display area NA to surround the display area DA, but a shape and a position of the first power line VDL are not limited thereto. A first source voltage (e.g., a high potential driving voltage of the pixels PX) may be supplied to the first power pad VDP. A first power line (e.g., a mesh-type first power line) connected to the first power line VDL positioned outside the display area DA may also be provided inside the display area DA, and accordingly, may transfer the first source voltage (e.g., the high potential driving voltage of the pixels PX) to the pixels PX. In an embodiment, the first power line VDL may be connected to at least one first dummy line DML1 and/or at least one second dummy line DML2. For example, some of the first dummy lines DML1 may be connected to the first power line VDL and the pixels PX to transfer the first source voltage to the pixels PX. In an embodiment, the first power line VDL may be formed as a multilayer line in at least a portion thereof. In an embodiment, the first power line VDL may include a plurality of lines having a relatively smaller width in the bending area BA than in the remaining area or the like of the sub-area SBA. A structure, a shape, the number, and/or a position of the first power line VDL may be variously changed according to embodiments.

The second power line VSL may be formed between at least one second power pad VSP provided in the pad area PA and the display area DA. In an embodiment, the second power line VSL may be formed in the non-display area NA to surround the display area DA, but a shape and a position of the second power line VSL are not limited thereto. A second source voltage (e.g., a low potential driving voltage of the pixels PX) may be supplied to the second power pad VSP. A second power line (e.g., a mesh-type second power line) connected to the second power line VSL positioned outside the display area DA may also be provided inside the display area DA to transfer the second source voltage to the pixels PX. In an embodiment, the second power line VSL may be connected to at least one first dummy line DML1 and/or at least one second dummy line DML2. For example, some of the second dummy lines DML2 may be connected to the second power line VSL and the pixels PX to transfer the second source voltage to the pixels PX. In an embodiment, the second power line VSL may be formed as a multilayer line in at least a portion thereof. In an embodiment, the second power line VSL may include a plurality of lines having a relatively smaller width in the bending area BA than in the remaining area or the like of the sub-area SBA. A structure, a shape, the number, and/or a position of the second power line VSL may be variously changed according to embodiments.

FIG. 6 is a circuit diagram illustrating a pixel PX according to an embodiment. FIG. 7 is a circuit diagram illustrating a pixel PX according to an embodiment. For example, FIGS. 6 and 7 illustrate different embodiments in relation to types of pixel transistors Tpx.

In FIGS. 6 and 7, embodiments in which scan lines SL connected to each pixel PX include a scan initialization line GIL, a scan control line GCL, a first scan line GWL1, and a second scan line GWL2 are illustrated. In addition, in FIGS. 6 and 7, embodiments in which power lines PL connected to each pixel PX include a first power line VDL, a second power line VSL, a first initialization voltage line VIL1, and a second initialization voltage lines VIL2 are illustrated. Types and the numbers of scan lines SL and power lines PL connected to each pixel PX may be changed depending on a structure of the pixel PX.

Referring to FIGS. 6 and 7, the pixel PX may include a light emitting unit EMU including at least one light emitting element EL and a pixel circuit PXC (also referred to as a “pixel driving unit”) connected to the light emitting unit EMU.

The light emitting element EL may be connected between the second power line VSL to which a second source voltage ELVSS is applied and the pixel circuit PXC. The light emitting element EL is a light source of the pixel PX and may emit light in response to a driving current supplied from the pixel circuit PXC.

The light emitting element EL may be an organic light emitting diode, but is not limited thereto. For example, the light emitting element EL may be an inorganic light emitting element, a quantum dot light emitting element, or other types of light emitting elements.

The pixel circuit PXC may control a light emitting timing and luminance of the light emitting element EL by controlling the driving current supplied to the light emitting element EL. The pixel circuit PXC may include at least one pixel transistor Tpx and a capacitor Cst. In an embodiment, the pixel circuit PXC may include pixel transistors Tpx including a driving transistor DT and switch elements, and the switch elements may include first to sixth transistors T1, T2, T3, T4, T5, and T6.

The driving transistor DT may include a gate electrode connected to a first node N1, a first electrode connected to the first power line VDL via the fourth transistor T4, and a second electrode connected to the light emitting unit EMU via the fifth transistor T5. One of the first electrode and the second electrode may be a source electrode, and the other of the first electrode and the second electrode may be a drain electrode. The driving transistor DT may control a source-drain current (hereinafter referred to as a “driving current”) flowing between the first electrode and the second electrode according to a voltage applied to the gate electrode (e.g., a voltage of the first node N1 corresponding to a voltage of a data signal).

The first transistor T1 may include a gate electrode connected to the first scan line GWL1, a first electrode connected to a data line DL, and a second electrode connected to the first electrode of the driving transistor DT. The first transistor T1 may be turned on by a first scan signal supplied to the first scan line GWL1 to connect the first electrode of the driving transistor DT to the data line DL. When the first transistor T1 is turned on, a voltage of a data signal supplied to the data line DL may be applied to the first electrode of the driving transistor DT.

The second transistor T2 may include a gate electrode connected to the scan control line GCL, a first electrode connected to the second electrode of the driving transistor DT, and a second electrode connected to the gate electrode of the driving transistor DT (or the first node N1). The second transistor T2 may be turned on by a scan control signal supplied to the scan control line GCL to connect the gate electrode and the second electrode of the driving transistor DT to each other. When the second transistor T2 is turned on, the driving transistor DT may be driven as a diode.

The third transistor T3 may include a gate electrode connected to the scan initialization line GIL, a first electrode connected to the gate electrode of the driving transistor DT, and a second electrode connected to the first initialization voltage line VIL1. The third transistor T3 may be turned on by a scan initialization signal of the scan initialization line GIL to connect the gate electrode of the driving transistor DT to the first initialization voltage line VIL1. When the third transistor T3 is turned on, a first initialization voltage VINT of the first initialization voltage line VIL1 may be applied to the gate electrode of the driving transistor DT.

The fourth transistor T4 may include a gate electrode connected to an emission control line ECL, a first electrode connected to the first power line VDL, and a second electrode connected to the first electrode of the driving transistor DT. The fourth transistor T4 may be turned on by an emission control signal supplied to the emission control line ECL to connect the first electrode of the driving transistor DT to the first power line VDL to which a first source voltage ELVDD is applied. When the fourth transistor T4 is turned on, the first source voltage ELVDD may be applied to the first electrode of the driving transistor DT.

The fifth transistor T5 may include a gate electrode connected to the emission control line ECL, a first electrode connected to the second electrode of the driving transistor DT, and a second electrode connected to the light emitting element EL. The fifth transistor T5 may be turned on by an emission control signal supplied to the emission control line ECL to connect the driving transistor DT to the light emitting element EL. When both the fourth transistor T4 and the fifth transistor T5 are turned on, the driving current having a magnitude corresponding to the voltage of the gate electrode of the driving transistor DT may flow to the light emitting element EL.

The sixth transistor T6 may include a gate electrode connected to the second scan line GWL2, a first electrode connected to an anode electrode of the light emitting element EL, and a second electrode connected to the second initialization voltage line VIL2. The sixth transistor T6 may be turned on by a second scan signal supplied to the second scan line GWL2 to connect the anode electrode of the light emitting element EL to the second initialization voltage line VIL2. The second scan signal may be a signal that is the same as or different from the first scan signal. When the sixth transistor T6 is turned on, a second initialization voltage VAINT of the second initialization voltage line VIL2 may be applied to the anode electrode of the light emitting element EL.

The capacitor Cst may be connected between the gate electrode of the driving transistor DT and the first power line VDL. The capacitor Cst may be charged with a voltage corresponding to the voltage of the data signal applied to the gate electrode of the driving transistor DT.

In an embodiment, an active layer (e.g., a semiconductor pattern including a channel region) of each of the pixel transistors Tpx (e.g., the driving transistor DT and the first to sixth transistors T1, T2, T3, T4, T5, and T6) may be made of one of polysilicon, amorphous silicon, and an oxide semiconductor. For example, as in an embodiment of FIG. 6, all of the pixel transistors Tpx may be formed as P-type transistors (e.g., P-type metal oxide semiconductor field effect transistor (MOSFETs)), and an active layer of each of the pixel transistors Tpx may be made of polysilicon or an oxide semiconductor.

Alternatively, as in an embodiment of FIG. 7, some of the pixel transistors Tpx, for example, the driving transistor DT and the first, fourth, fifth, and sixth transistors T1, T4, T5, and T6 may be formed as P-type transistors, and the others of the pixel transistors Tpx, for example, the second transistor T2 and the third transistor T3 may be formed as N-type transistors (e.g., N-type MOSFETs). In an embodiment, an active layer of each of the driving transistor DT and the first, fourth, fifth, and sixth transistors T1, T4, T5, and T6 formed as the P-type transistors may be made of polysilicon, and an active layer of each of the second transistor T2 and the third transistor T3 formed as the N-type transistors may be made of an oxide semiconductor. In an embodiment, the transistors including the respective active layers made of the polysilicon and the transistors including the respective active layers made of the oxide semiconductor may be disposed at different layers on the substrate 100.

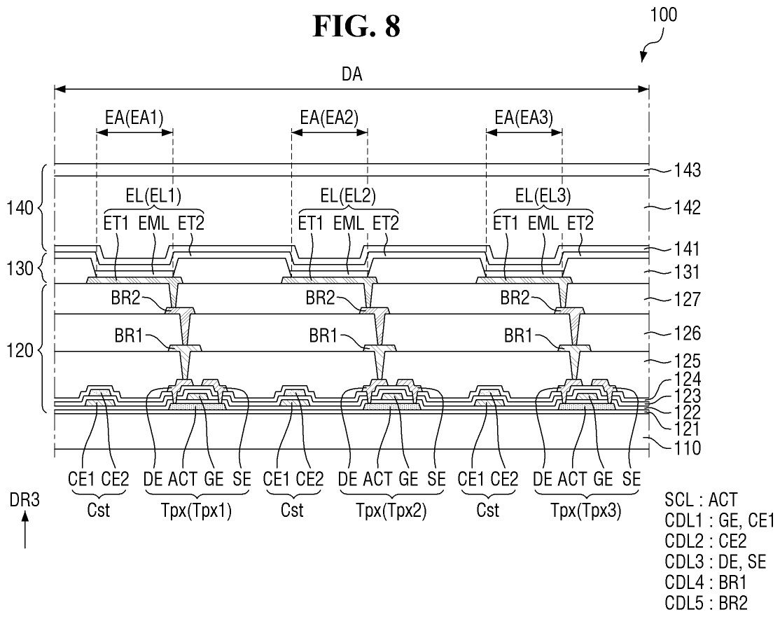

FIG. 8 is a cross-sectional view illustrating the display panel 100 according to an embodiment. For example, FIG. 8 schematically illustrates a cross section of a portion of the display area DA corresponding to an area in which three pixels PX adjacent to each other are disposed. FIG. 8 schematically illustrates cross-sections of one pixel transistor Tpx, a capacitor Cst, and a light emitting element EL among elements provided to each pixel PX. Cross-sections of the pixels PX may be variously changed according to types, structures, and the like of the respective pixels PX and the display panel 100 including the respective pixels PX.

Referring to FIGS. 1 to 8, the display panel 100 may include the substrate 110, and the circuit layer 120, the light emitting element layer 130, and the encapsulation layer 140 that are disposed on the substrate 110. The circuit layer 120, the light emitting element layer 130, and the encapsulation layer 140 may be sequentially disposed or stacked on the substrate 110 along the third direction DR3.

The substrate 110 may be made of a material having flexible characteristics to be able to be bent, folded, or rolled. The substrate 110 may be made of an insulating material such as a polymer resin. As an example, the substrate 110 may be made of polyimide.

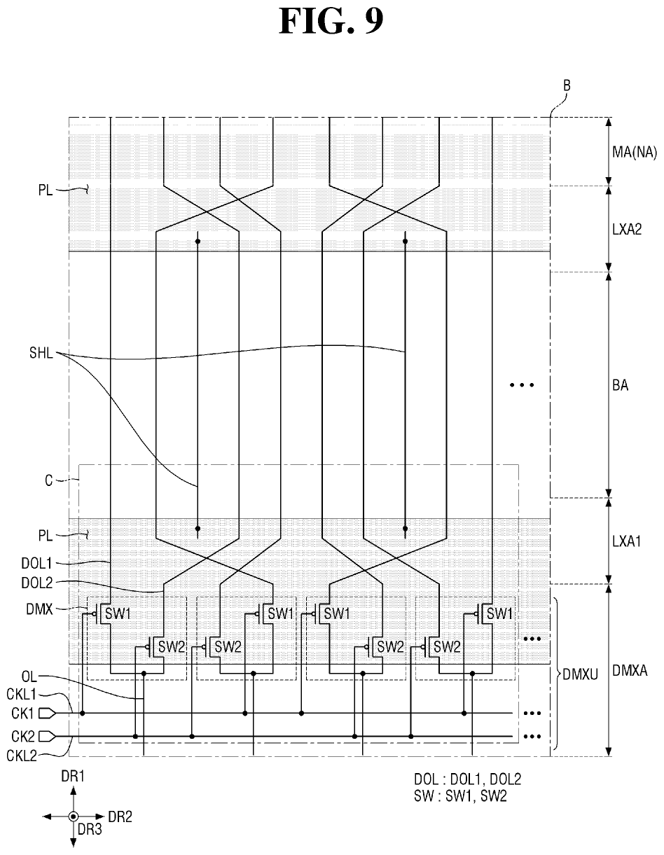

The circuit layer 120 may include the pixel circuits PXC of the pixels PX (e.g., circuit elements constituting the pixel circuits PXC of the respective pixels PX) and the lines (e.g., the data lines DL, the connection lines DCL, the data output lines DOL, the output lines OL of the driving circuit 200, the data input lines DIL, and the power lines PL (e.g., the first power line VDL and the second power line VSL) of FIGS. 4 and 5) and/or the dummy lines DML connected to the pixels PX. The circuit layer 120 may further include demultiplexer circuits (e.g., first switches SW1 and second switches SW2 of demultiplexer circuits DMX of FIG. 9) arranged in the demultiplexer area DMXA of the sub-area SBA.

In FIG. 8, any one pixel transistor Tpx and a capacitor Cst provided to each pixel PX among the circuit elements that may be provided in the circuit layer 120 in the display area DA are illustrated. The pixel transistor Tpx may be disposed in a pixel area of a corresponding pixel PX and may be electrically connected to a light emitting element EL of the corresponding pixel PX. Each pixel transistor Tpx may include an active layer ACT, a gate electrode GE, a source electrode SE, and a drain electrode DE.

The circuit layer 120 may include conductive layers for forming the circuit elements and the lines, at least one semiconductor layer SCL, and insulating layers disposed between the conductive layers and the semiconductor layer SCL. For example, the circuit layer 120 may include a buffer layer 121, a semiconductor layer SCL (or a first semiconductor layer), a first insulating layer 122 (e.g., a first gate insulating layer), a first conductive layer CDL1 (e.g., a first gate insulating layer), a second insulating layer 123 (e.g., a second gate insulating layer), a second conductive layer CDL2 (e.g., a second gate conductive layer), a third insulating layer 124 (e.g., an interlayer insulating layer or a first interlayer insulating layer), a third conductive layer CDL3 (e.g., a first source-drain conductive layer), a fourth insulating layer 125 (e.g., a first via layer or a first planarization layer), a fourth conductive layer CDL4 (e.g., a second source-drain conductive layer), a fifth insulating layer 126 (e.g., a second via layer or a second planarization layer), a fifth conductive layer CDL5 (e.g., a third source-drain conductive layer), and a sixth insulating layer 127 (e.g., a third via layer or a third planarization layer) that are sequentially disposed on the substrate 110 based on the third direction DR3.

The buffer layer 121 may include at least one inorganic film including an inorganic insulating material (e.g., silicon nitride, silicon oxide, silicon oxynitride, titanium oxide, aluminum oxide, or other inorganic insulating materials). However, embodiments are not limited thereto, and a material of the buffer layer 121 may be changed.

In an embodiment, an additional conductive layer may be disposed between the substrate 110 and the buffer layer 121. For example, a conductive layer including a bottom metal layer (BML) and/or at least one line (or a portion of the at least one line) overlapping the active layer ACT of at least one pixel transistor Tpx may be disposed between the substrate 110 and the buffer layer 121.

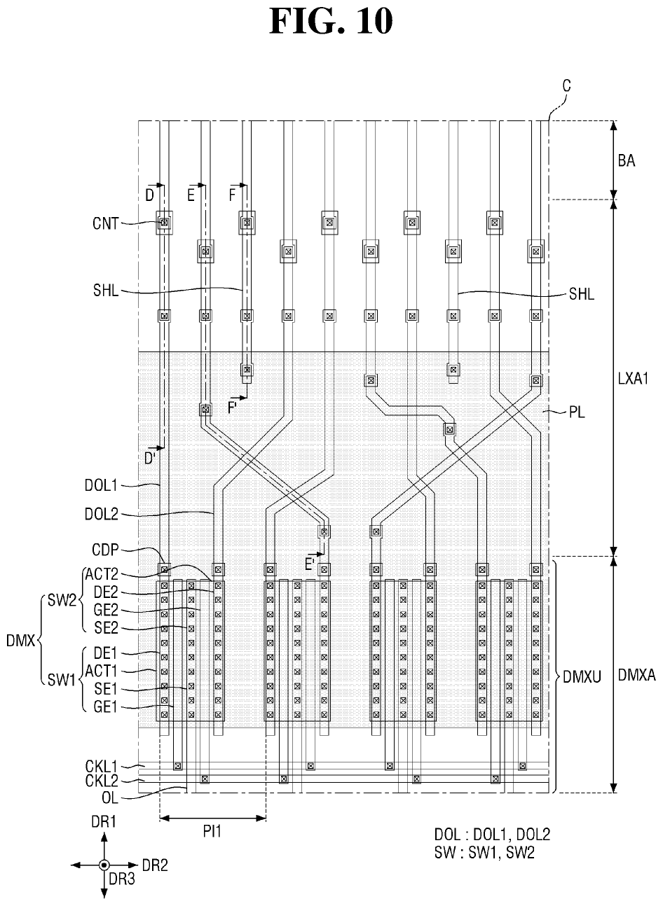

The semiconductor layer SCL may be provided on one surface of the substrate 110 including the buffer layer 121. The semiconductor layer SCL may include the active layer ACT of each of the pixel transistors Tpx. In an embodiment, the semiconductor layer SCL may further include active layers (e.g., a first active layer ACT1 and a second active layer ACT2 of FIG. 10) of each of switches (e.g., first switches SW1 and second switches SW2 of FIGS. 9 and 10) provided in the demultiplexer unit DMXU. Each active layer ACT may include polycrystalline silicon, single crystal silicon, low-temperature polycrystalline silicon, amorphous silicon, or an oxide semiconductor material. Each active layer ACT may include a channel region, a source region, and a drain region.

The first insulating layer 122 may cover the semiconductor layer SCL. In an embodiment, the first insulating layer 122 may include at least one inorganic film including an inorganic insulating material.

The first conductive layer CDL1 may be provided on the first insulating layer 122. The first conductive layer CDL1 may include a gate electrode GE of each of the pixel transistors Tpx. In an embodiment, the first conductive layer CDL1 may further include gate electrodes (e.g., a first gate electrode GE1 and a second gate electrode GE2 of FIG. 10) of each of the switches provided in the demultiplexer unit DMXU. Each gate electrode GE may include a conductive material (e.g., at least one of molybdenum (Mo), aluminum (Al), chromium (Cr), gold (Au), titanium (Ti), nickel (Ni), neodymium (Nd), copper (Cu), and other metals, alloys thereof, or other conductive materials) and may be a single-layer or multilayer electrode.

The first conductive layer CDL1 may further include at least one line (or a portion of the at least one line), a bridge pattern, and/or a capacitor electrode. As an example, the first conductive layer CDL1 may further include a first capacitor electrode CE1 of the capacitor Cst.

The second insulating layer 123 may cover the first conductive layer CDL1. In an embodiment, the second insulating layer 123 may include at least one inorganic film including an inorganic insulating material.

The second conductive layer CDL2 may be provided on the second insulating layer 123. The second conductive layer CDL2 may further include at least one line (or a portion of the at least one line), a bridge pattern, and/or a capacitor electrode. As an example, the second conductive layer CDL2 may include a second capacitor electrode CE2 of the capacitor Cst.

In an embodiment, when each pixel PX further includes at least one transistor formed at a different layer from the pixel transistors Tpx illustrated in FIG. 8, the second conductive layer CDL2 may further include a gate electrode of the at least one transistor, a bottom metal layer, or the like.

The third insulating layer 124 may cover the second conductive layer CDL2. In an embodiment, the third insulating layer 124 may include at least one inorganic film including an inorganic insulating material.

The third conductive layer CDL3 may be provided on the third insulating layer 124. The third conductive layer CDL3 may include the source electrode SE and the drain electrode DE of each of the pixel transistors Tpx. In an embodiment, the third conductive layer CDL3 may further include source electrodes and drain electrodes (e.g., a first source electrode SE1, a second source electrode SE2, a first drain electrode DE1, and a second drain electrode DE2 of FIG. 10) of each of the switches provided in the demultiplexer unit DMXU. Each of the source electrode SE and the drain electrode DE may include a conductive material and may be a single-layer or multilayer electrode. In another embodiment, the source electrode SE and the drain electrode DE of each of the pixel transistors Tpx may be formed as a source region and a drain region of the active layer ACT, and the third conductive layer CDL3 may include a bridge pattern or the like connected to the source electrode SE or the drain electrode DE of at least one pixel transistor Tpx.

The third conductive layer CDL3 may further include at least one line (or a portion of the at least one line), a bridge pattern, and/or a capacitor electrode. As an example, the third conductive layer CDL3 may include portions of the first power line VDL and/or the second power line VSL provided inside and/or outside the display area DA.

The fourth insulating layer 125 may cover the third conductive layer CDL3. In an embodiment, the fourth insulating layer 125 may include at least one organic film including an organic insulating material (e.g., an acrylic resin, an epoxy resin, a phenolic resin, a polyamide resin, a polyimide resin, or other organic insulating materials) in order to planarize the circuit layer 120.

The fourth conductive layer CDL4 may be provided on the fourth insulating layer 125. The fourth conductive layer CDL4 may include first bridge electrodes BR1 (or first connection electrodes) connecting the pixel transistors Tpx to respective light emitting elements EL. Each first bridge electrode BR1 may be disposed on each pixel transistor Tpx, and may electrically connect the pixel transistor Tpx to a light emitting element EL of a corresponding pixel PX. As an example, a first bridge electrode BR1 of a first pixel including a first pixel transistor Tpx1 and a first light emitting element EL1 may connect the first pixel transistor Tpx1 to the first light emitting element EL1. Similarly, a first bridge electrode BR1 of a second pixel including a second pixel transistor Tpx2 and a second light emitting element EL2 may connect the second pixel transistor Tpx2 to the second light emitting element EL2, and a first bridge electrode BR1 of a third pixel including a third pixel transistor Tpx3 and a third light emitting element EL3 may connect the third pixel transistor Tpx3 to the third light emitting element EL3. Each first bridge electrode BR1 may include a conductive material and may be a single-layer or multilayer electrode.

The fourth conductive layer CDL4 may further include at least one line (or a portion of the at least one line), a bridge pattern, and the like. As an example, the fourth conductive layer CDL4 may include portions of the first power line VDL and/or the second power line VSL inside and/or outside the display area DA.

The fifth insulating layer 126 may cover the fourth conductive layer CDL4. In an embodiment, the fifth insulating layer 126 may include at least one organic film including an organic insulating material (e.g., an acrylic resin, an epoxy resin, a phenolic resin, a polyamide resin, a polyimide resin, or other organic insulating materials) in order to planarize the circuit layer 120.

The fifth conductive layer CDL5 may be provided on the fifth insulating layer 126. The fifth conductive layer CDL5 may include second bridge electrodes BR2 (or second connection electrodes) connecting the pixel transistors Tpx to the respective light emitting elements EL. As an example, each second bridge electrode BR2 may be disposed on each first bridge electrode BR1, and may electrically connect the first bridge electrode BR1 to the light emitting element EL of the corresponding pixel PX. As an example, a second bridge electrode BR2 of the first pixel including the first pixel transistor Tpx1 and the first light emitting element EL1 may connect the first bridge electrode BR1 of the first pixel to the first light emitting element EL1. Similarly, a second bridge electrode BR2 of the second pixel including the second pixel transistor Tpx2 and the second light emitting element EL2 may connect the first bridge electrode BR1 of the second pixel to the second light emitting element EL2, and a second bridge electrode BR2 of the third pixel including the third pixel transistor Tpx3 and the third light emitting element EL3 may connect the first bridge electrode BR1 of the third pixel to the third light emitting element EL3. Each second bridge electrode BR2 may include a conductive material and may be a single-layer or multilayer electrode.

The fifth conductive layer CDL5 may further include at least one line (or a portion of the at least one line), a bridge pattern, and the like. As an example, the fifth conductive layer CDL5 may include portions of the first power line VDL and/or the second power line VSL inside and/or outside the display area DA.

The sixth insulating layer 127 may cover the fifth conductive layer CDL5. In an embodiment, the sixth insulating layer 127 may include at least one organic film including an organic insulating material (e.g., an organic insulating material exemplified as the material of the fourth insulating layer 125 or other organic insulating materials) in order to planarize the circuit layer 120.

The light emitting element layer 130 may include a pixel defining film 131 partitioning emission areas EA and the respective light emitting elements EL positioned in the respective emission areas EA. For example, the light emitting element layer 130 may include a first light emitting element EL1 disposed in an emission area EA (e.g., a first emission area EA1) of the first pixel, a second light emitting element EL2 disposed in an emission area EA (e.g., a second emission area EA2) of the second pixel, and a third light emitting element EL3 disposed in an emission area EA (e.g., a third emission area EA3) of the third pixel.

Each light emitting element EL may include a first electrode ET1 (e.g., an anode electrode) connected to each pixel transistor Tpx through the first bridge electrode BR1, the second bridge electrode BR2, and the like, and a light emitting layer EML and a second electrode ET2 (e.g., a cathode electrode) that are sequentially disposed on the first electrode ET1. In an embodiment, the light emitting element EL may further include a first intermediate layer (e.g., a hole layer including a hole transport layer) interposed between the first electrode ET1 and the light emitting layer EML and a second intermediate layer (e.g., an electron layer including an electron transport layer) interposed between the light emitting layer EML and the second electrode ET2.

The first electrode ET1 of the light emitting element EL may include a conductive material and may be disposed on the circuit layer 120. For example, the first electrode ET1 may be disposed on the sixth insulating layer 127 to correspond to each emission area EA. In an embodiment, the first electrode ET1 may include a metal material having high reflectivity. For example, the first electrode ET1 may have a single-layer structure of molybdenum (Mo), titanium (Ti), copper (Cu), or aluminum (Al) or have a multilayer structure (e.g., ITO/Mg, ITO/MgF, ITO/Ag, ITO/Ag/ITO, etc.) including indium-tin-oxide (ITO), indium-zinc-oxide (IZO), zinc oxide (ZnO), or indium oxide (In₂O₃), and silver (Ag), magnesium (Mg), aluminum (Al), platinum (Pt), lead (Pb), gold (Au), nickel (Ni), or the like.

The light emitting layer EML of the light emitting element EL may include a high molecular material or a low molecular material. Light emitted from the light emitting layer EML may contribute to image display. In an embodiment, the light emitting layer EML may be provided for each pixel PX, and the light emitting layer EML of each pixel PX may emit visible light of a color corresponding to the corresponding pixel PX. In another embodiment, the light emitting layer EML may be a common layer shared by the pixels PX of different colors, and wavelength conversion layers and/or color filters corresponding to colors (or wavelength bands) of light to be emitted from the respective pixels PX may be disposed in the emission areas EA of at least some of the pixels PX.

The second electrode ET2 of the light emitting element EL may include a conductive material and may be connected to the second power line VSL. In an embodiment, the second electrode ET2 may be a common film formed over the entire display area DA in a form in which it covers the light emitting layers EML and the pixel defining film 131. In an embodiment, the second electrode ET2 may be made of a transparent conductive material (TCO) such as ITO or IZO capable of transmitting light therethrough or a semi-transmissive conductive material such as magnesium (Mg), silver (Ag), or an alloy of magnesium (Mg) and silver (Ag). When the second electrode ET2 is made of the semi-transmissive conductive material, an improvement in light emission efficiency due to a micro cavity effect may be expected.

The pixel defining film 131 may have openings corresponding to the respective emission areas EA and surround the emission areas EA. For example, the pixel defining film 131 may be formed to cover an edge of the first electrode ET1 of each of the light emitting elements EL, and may include an opening exposing the other portion of the first electrode ET1. An area in which the exposed first electrode ET1 and the emission layer EML overlap each other (or an area including such an area) may be defined as the emission area EA of each pixel PX.

In an embodiment, the pixel defining film 131 may include at least one organic film including an organic insulating material. For example, the pixel defining film 131 may include a polyacrylates resin, an epoxy resin, a phenolic resin, a polyamides resin, a polyimides resin, an unsaturated polyesters resin, a polyphenyleneethers resin, a polyphenylenesulfides resin, benzocyclobutene (BCB), or other organic insulating materials.

The encapsulation layer 140 may be disposed on the light emitting element layer 130 in the display area DA and the non-display area NA positioned around the display area DA. The encapsulation layer 140 may block penetration of oxygen or moisture into the light emitting element layer 130 and alleviate an electrical or physical impact on the circuit layer 120 and the light emitting element layer 130.

In an embodiment, the encapsulation layer 140 may include a first encapsulation layer 141, a second encapsulation layer 142, and a third encapsulation layer 143 that are sequentially disposed on the light emitting element layer 130. The first encapsulation layer 141 and the third encapsulation layer 143 may include an inorganic insulating material, and the second encapsulation layer 142 may include an organic insulating material.

FIG. 9 is a circuit diagram illustrating a demultiplexer unit DMXU and lines around the demultiplexer unit DMXU according to an embodiment. For example, FIG. 9 illustrates an embodiment of circuit configurations of demultiplexer circuits DMX positioned in area B of FIG. 5 and data output lines DOL and shield lines SHL around the demultiplexer circuits DMX.

Referring to FIG. 9, the demultiplexer unit DMXU may include demultiplexer circuits DMX provided in the demultiplexer area DMXA and connected between the output lines OL of the driving circuit 200 and the data output lines DOL (output lines of the demultiplexer unit DMXU). Each of the demultiplexer circuits DMX may include a first switch SW1 and a second switch SW2.

Each demultiplexer circuit DMX may include a pair of switches SW connected between one output line OL connected to the driving circuit 200 and a pair of data output lines DOL and driven at different timings. For example, each demultiplexer circuit DMX may include a first switch SW1 connected between one output line OL connected to the driving circuit 200 and one first line (also referred to as a “first data output line”) DOL1 and a second switch SW2 connected between the one output line OL and one second line (also referred to as a “second data output line”) DOL2. The first switch SW1 may be turned on in response to a first clock signal CK1 supplied from a first clock line CKL1, and the second switch SW2 may be turned on in response to a second clock signal CK2 supplied from a second clock line CKL2.

The first clock signal CK1 and the second clock signal CK2 may have gate-on voltages at different points in time. Accordingly, the first switch SW1 and the second switch SW2 may be turned on at different points in time. For example, the first clock signal CK1 and the second clock signal CK2 may alternately have gate-on voltages, and the first switch SW1 and the second switch SW2 may be alternately turned on. When the first switch SW1 is turned on, a data signal (e.g., a data voltage) supplied from the driving circuit 200 through the output line OL may be output to the first line DOL1, and, when the switch SW2 is turned on, the data signal supplied from the driving circuit 200 through the output line OL may be output to the second line DOL2.

The data output lines DOL may include first lines DOL1 connected to the respective first switches SW1 and second lines DOL2 connected to the respective second switches SW2. The first lines DOL1 and the second lines DOL2 may extend from the demultiplexer area DMXA to the main area MA through the bending area BA, and may be connected to the respective data lines DL inside and/or around the display area DA.

The first lines DOL1 may connect the first switches SW1 to the data lines DL, respectively. The second lines DOL2 may connect the second switches SW2 to the data lines DL, respectively.

In the demultiplexer area DMXA and the main area MA, the first lines DOL1 and the second lines DOL2 may be sequentially arranged along the second direction DR2 in an order corresponding to an order in which the respective demultiplexer circuits DMX are arranged. In the first line crossing area LXA1 and the second line crossing area LXA2, at least some of the first lines DOL1 and at least some of the second lines DOL2 may cross each other. For example, in the first line crossing area LXA1, some of the first lines DOL1 and some of the second lines DOL2 may cross each other, such that an arrangement order of the first lines DOL1 and the second lines DOL2 may be changed, and in the second line crossing area LXA2, some of the first lines DOL1 and some of the second lines DOL2 crossing each other in the first line crossing area LXA1 may cross each other again, such that an arrangement order of the first lines DOL1 and the second lines DOL2 may be restored to be the same as an arrangement order of the first lines DOL1 and the second lines DOL2 in the demultiplexer area DMXA. Accordingly, an arrangement order of the first lines DOL1 and the second lines DOL2 in the bending area BA may be different from an arrangement order of the first lines DOL1 and the second lines DOL2 in the demultiplexer area DMXA and the main area MA.

In the bending area BA, a plurality of first lines DOL1 including at least two first lines DOL1 and a plurality of second lines DOL2 including at least two second lines DOL2 may be alternately arranged, and the shield lines SHL may be disposed between the plurality of first lines DOL1 and the plurality of second lines DOL2. For example, in the bending area BA, a plurality of first lines DOL1 such as two, four, or eight first lines DOL1 may be sequentially and/or continuously arranged along the second direction DR2 to form respective first line groups, and a plurality of second lines DOL2 such as two, four, or eight second lines DOL2 may be sequentially and/or continuously arranged along the second direction DR2 to form respective second line groups. The first line groups and the second line groups may be alternately arranged along the second direction DR2, and at least one shield line SHL may be disposed between the first line group and the second line group disposed adjacent to each other.

The shield lines SHL may be positioned at least in the bending area BA and may be disposed between the first lines DOL1 and the second lines DOL2. The shield lines SHL may be connected to the power lines PL around the bending area BA.

For example, the shield lines SHL may extend from the bending area BA to the first line crossing area LXA1 and the second line crossing area LXA2. Each of the shield lines SHL may overlap any one power line PL in the first line crossing area LXA1 and/or the second line crossing area LXA2, and may be connected to any one power line PL. As an example, both ends of each of the shield lines SHL may be positioned in the first line crossing area LXA1 and the second line crossing area LXA2, may overlap the first power line VDL or the second power line VSL, and may be electrically connected to the first power line VDL or the second power line VSL through at least one contact hole.

According to the above-described embodiment, the data output lines DOL (e.g., the first lines DOL1 or the second lines DOL2) connected to the switches SW (e.g., the first switches SW1 or the second switches SW2) driven at the same time and disposed in the bending area BA or the like adjacent to the demultiplexer area DMXA may be grouped into several groups and be disposed adjacent to each other. In addition, the shield lines SHL receiving a constant voltage may be disposed between the data output lines DOL (e.g., the first lines DOL1 and the second lines DOL2) connected to the switches SW (e.g., the first switches SW1 and the second switches SW2) driven at different points in time. Accordingly, it is possible to reduce, prevent, or shield coupling between the data output lines DOL to prevent voltage fluctuations of the data signals and stably transfer the respective data signals to the pixels PX.

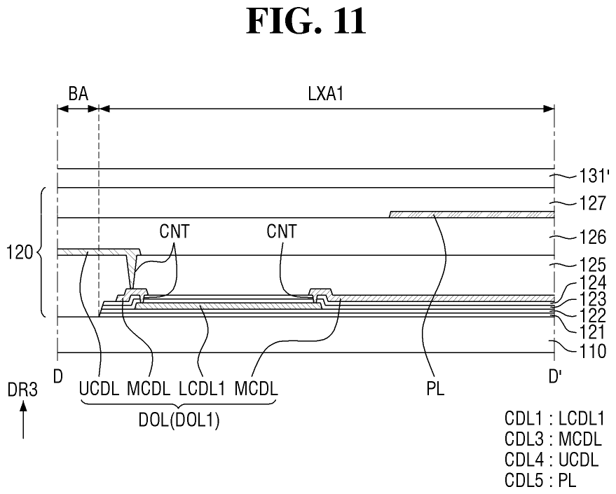

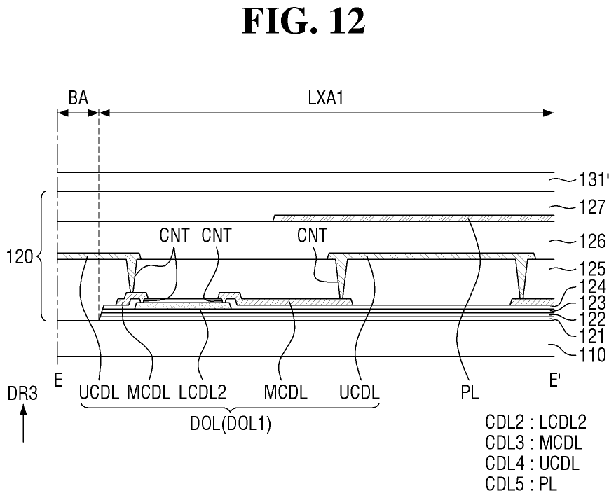

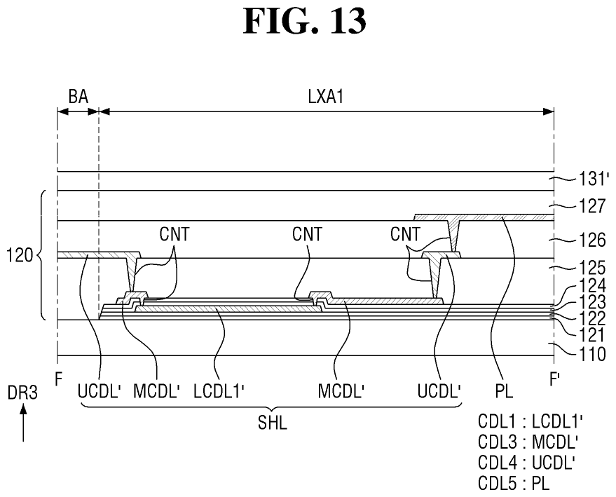

FIG. 10 is a plan view illustrating area C of FIG. 9. FIG. 11 is a cross-sectional view illustrating an embodiment of a cross section taken along line D-D′ of FIG. 10. FIG. 12 is a cross-sectional view illustrating an embodiment of a cross section taken along line E-E′ of FIG. 10. FIG. 13 is a cross-sectional view illustrating an embodiment of a cross section taken along line F-F′ of FIG. 10.

Referring to FIGS. 10 to 13, the demultiplexer circuits DMX and lines around the demultiplexer circuits DMX may be disposed in the circuit layer 120 of the display panel 100. The demultiplexer circuits DMX may be arranged in the demultiplexer area DMXA at substantially the same pitch as the pixels PX in the second direction DR2. For example, the demultiplexer circuits DMX may be sequentially arranged in the demultiplexer area DMXA at the first pitch PIl in the second direction DR2. Accordingly, the data output lines DOL may be formed as lines having a substantially straight line shape.

Each first switch SW1 may include a first gate electrode GE1 connected to the first clock line CKL1, a first source electrode SE1 (or a first drain electrode) connected to the output line OL of the driving circuit 200, a first drain electrode DE1 (or a first source electrode) connected to the first line DOL1, and a first active layer ACT1 connected between the first source electrode SE1 and the first drain electrode DE1. Each second switch SW2 may include a second gate electrode GE2 connected to the second clock line CKL2, a second source electrode SE2 (or a second drain electrode) connected to the output line OL of the driving circuit 200, a second drain electrode DE2 (or a second source electrode) connected to the second line DOL2, and a second active layer ACT2 connected between the second source electrode SE2 and the second drain electrode DE2. At least one contact part CNT including at least one contact hole may be formed in order to electrically connect at least two elements disposed at different layers to each other. For convenience, in FIG. 10, only one contact part CNT (e.g., one contact part CNT connecting the first line DOL1 to a respective data line) is denoted by a reference symbol.

In an embodiment, each first switch SW1 and/or second switch SW2 may be formed simultaneously with at least one pixel transistor Tpx (e.g., the pixel transistor of FIG. 8) included in each pixel circuit PXC, and may have a cross-sectional structure substantially the same as or similar to that of the at least one pixel transistor Tpx. As an example, the first active layer ACT1 and the second active layer ACT2 may be provided or disposed at the semiconductor layer SCL of the circuit layer 120 together with the active layer ACT of the pixel transistor Tpx, and the first gate electrode GE1 and the second gate electrode GE2 may be provided or disposed at the first conductive layer CDL1 of the circuit layer 120 together with the gate electrode GE of the pixel transistor Tpx. The first source electrode SE1, the first drain electrode DE1, the second source electrode SE2, and the second drain electrode DE2 may be provided or disposed at the third conductive layer CDL3 of the circuit layer 120 together with the source electrode SE and the drain electrode DE of the pixel transistor Tpx. In an embodiment, a connection part between the first drain electrode DE1 and the first line DOL1 may be formed as multiple layers including at least one conductive pattern CDP disposed at a different layer (e.g., the fourth conductive layer CDL4 of the circuit layer 120) from the first drain electrode DE1.

Structures of the demultiplexer circuits DMX are not limited to the above-described embodiment. For example, structures of the demultiplexer circuits DMX, positions of the demultiplexer circuits DMX in a cross-sectional view, and the like, may be variously changed according to embodiments.

Similarly, structures and/or positions of the lines may be variously changed according to embodiments. For example, each line may be formed as a single-layer line or may be formed as a multilayer line in at least a portion thereof. In addition, at least one line may extend while being provided at different conductive layers for each section or for each area and changing a layer at which it is disposed within the circuit layer 120.

The data output lines DOL may be formed as straight lines extending in the first direction DR1 in areas other than the first line crossing area LXA1 and the second line crossing area LXA2, for example, the demultiplexer area DMXA, the bending area BA, and the main area MA. As an example, the demultiplexer circuits DMX are disposed at the first pitch PIl like the pixels PX (e.g., the pixel circuits PXC) and/or the data lines DL in the second direction DR2, and accordingly, the data output lines DOL may be formed as substantial straight lines. Accordingly, lengths and a length deviation of the data output lines DOL may be reduced or minimized.

The data output lines DOL may be provided or disposed at least one of the first conductive layer CDL1, the second conductive layer CDL2, the third conductive layer CDL3, and the fourth conductive layer CDL4 of the circuit layer 120 in the demultiplexer area DMXA, the first line crossing area LXA1, the bending area BA, and the second line crossing area LXA2. For example, the data output lines DOL may include respective middle line layers MCDL provided at the third conductive layer CDL3 in portions of the demultiplexer area DMXA and the first line crossing area LXA1. In an embodiment, some (e.g., a first line DOL1 connected to a first switch SW1 of a second demultiplexer circuit DMX of FIG. 10 and arranged second left in the bending area BA) of the data output lines DOL may include respective upper line layers UCDL provided at a conductive layer different from the third conductive layer CDL3, for example, the fourth conductive layer CDL4 in the first line crossing area LXA1 and the second line crossing area LXA2 in order to secure insulation from the other data output lines DOL crossing some of the data output lines DOL.

In an embodiment, each of the data output lines DOL may include a first lower line layer LCDL1 provided at the first conductive layer CDL1 or a second lower line layer LCDL2 provided at the second conductive layer CDL2, in portions or the like of the first line crossing area LXA1 and/or the second line crossing area LXA2. As an example, the data output lines DOL and the shield lines SHL may be alternately provided at the first conductive layer CDL1 and the second conductive layer CDL2 in a portion of each of the first line crossing area LXA1 and the second line crossing area LXA2. Accordingly, damage to the data output lines DOL and the shield lines SHL due to static electricity or the like may be prevented, and electrical stability of the data output lines DOL and the shield lines SHL may be secured.

The data output lines DOL may be provided or disposed at the fourth conductive layer CDL4 in the bending area BA. For example, the data output lines DOL may include an upper line layer UCDL provided at the fourth conductive layer CDL4 in the bending area BA.

Inorganic insulating layers provided in the circuit layer 120, for example, the buffer layer 121, the first insulating layer 122, the second insulating layer 123, and the third insulating layer 124 may be removed in the bending area BA. Accordingly, damage (e.g., cracks) of the inorganic insulating layers due to bending may be prevented, and flexibility of the display panel 100 in the bending area BA may be increased.

Organic insulating layers provided in the circuit layer 120, for example, the fourth insulating layer 125, the fifth insulating layer 126, and the sixth insulating layer 127 may be provided even in at least a portion of the sub-area SBA including the bending area BA. Accordingly, an impact due to bending may be alleviated and lines disposed in the sub-area SBA may be stably protected. In an embodiment, at least one organic insulating layer may be further disposed on the sixth insulating layer 127 even in the sub-area SBA. For example, an organic insulating layer 131′ disposed at the same layer as the pixel defining film 131 may be further disposed on the sixth insulating layer 127 in the bending area BA or the like.

The shield lines SHL may be provided or disposed at the fourth conductive layer CDL4 in the bending area BA. For example, each of the shield lines SHL may include an upper line layer UCDL′ provided at the fourth conductive layer CDL4 in the bending area BA.

The shield lines SHL may be provided or disposed at least one of the first conductive layer CDL1, the second conductive layer CDL2, the third conductive layer CDL3, and the fourth conductive layer CDL4 in the first line crossing area LXA1 and the second line crossing area LXA2. For example, each of the shield lines SHL may include at least one of a first lower line layer LCDL1′ provided at the first conductive layer CDL1 (or a second lower line layer provided at the second conductive layer CDL2), a middle line layer MCDL′ provided at the third conductive layer CDL3, and an upper line layer UCDL′ provided at the fourth conductive layer CDL4 in the first line crossing area LXA1 and the second line crossing area LXA2.

The shield lines SHL may be connected to the power lines PL in the first line crossing area LXA1 and/or the second line crossing area LXA2. For example, each of the shield lines SHL may be electrically connected to the power line PL (e.g., the first power line VDL or the second power line VSL) overlapping each shield line SHL in the first line crossing area LXA1 and the second line crossing area LXA2.

In an embodiment, the data output lines DOL and the shield lines SHL may be arranged at uniform intervals along the second direction DR2. For example, at least in the bending area BA, the data output lines DOL and the shield lines SHL may be arranged at uniform intervals along the second direction DR2.

The power lines PL may be provided or disposed at the fifth conductive layer CDL5 in the first line crossing area LXA1 and the second line crossing area LXA2. In an embodiment, each of the power lines PL may overlap at least one shield line CHL, and may be connected to the at least one shield line CHL.

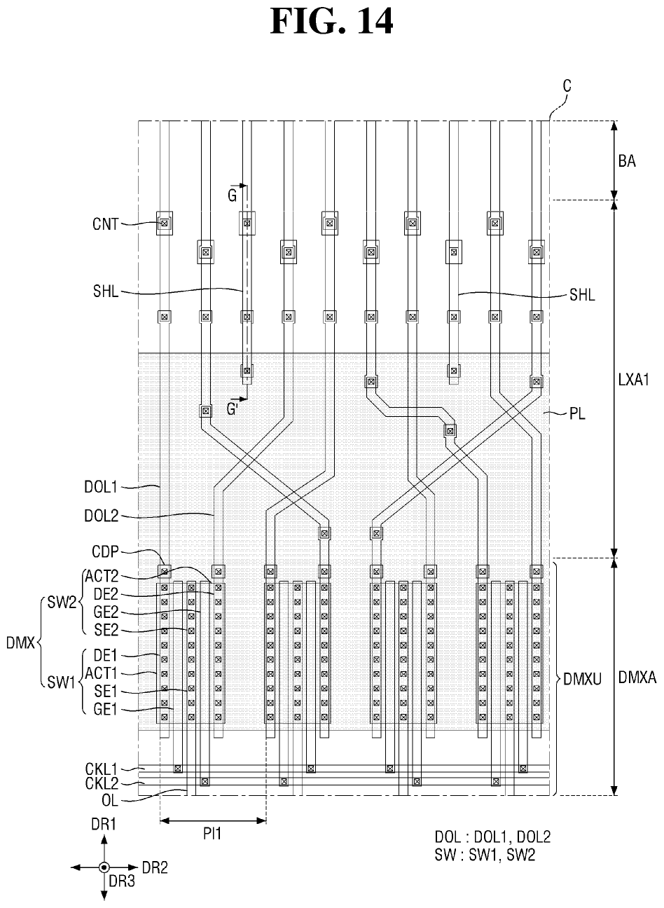

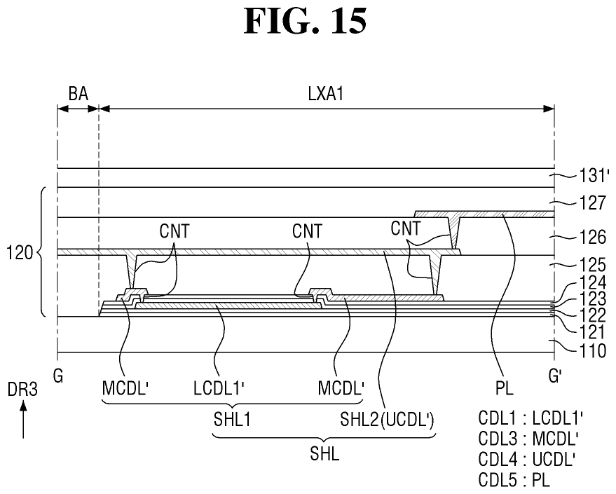

FIG. 14 is a plan view illustrating area C of FIG. 9. For example, FIG. 14 illustrates a modified embodiment of an embodiment of FIG. 10 in relation to the shield lines SHL. FIG. 15 is a cross-sectional view illustrating an embodiment of a cross section taken along line G-G′ of FIG. 14.

Referring to FIGS. 14 and 15, the shield lines SHL may be formed as multilayer lines in the first line crossing area LXA1 and/or the second line crossing area LXA2. For example, in the first line crossing area LXA1 and the second line crossing area LXA2, each of the shield lines SHL may be formed as a multilayer line including a first line layer SHL1 (e.g., a first lower conductive layer LCDL1′, a second lower conductive layer, and/or a middle conductive layer MCDL′) provided at least one of the first conductive layer CDL1, the second conductive layer CDL2, and the third conductive layer CDL3 and a second line layer SHL2 (e.g., an upper line layer UCDL′) provided at the fourth conductive layer CDL4. Accordingly, resistance of at least one power line PL connected to the shield lines SHL may be reduced, and a source voltage drop and heat generation in the power line PL may be prevented or reduced.

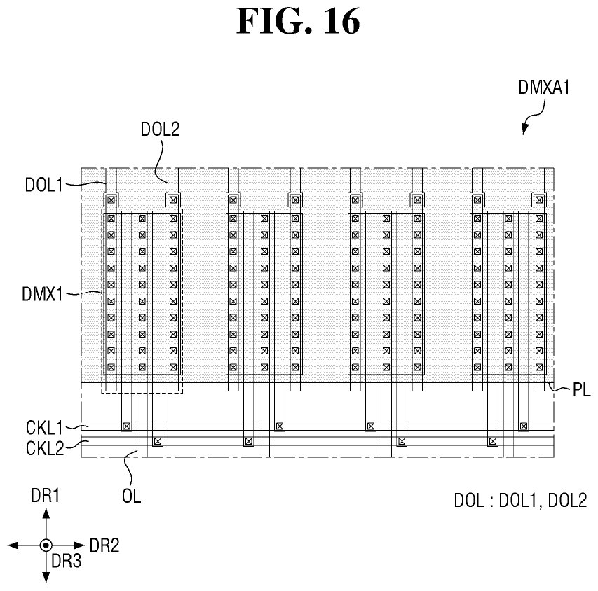

FIG. 16 is a plan view illustrating a first demultiplexer area DMXA1 according to an embodiment.

Referring to FIG. 16, first demultiplexer circuits DMX1 may be positioned in the first demultiplexer area DMXA1. The first demultiplexer circuits DMX1 may be connected to the first data lines DL1 and the second data lines DL2 through the respective data output lines DOL. For example, some of the first lines DOL1 and the second lines DOL2 connected to the first demultiplexer circuits DMX1 may be connected to the second data lines DL2. The others of the first lines DOL1 and the second lines DOL2 connected to the first demultiplexer circuits DMX1 may be connected to the first data lines DL1 via the respective connection lines DCL passing through the boundary between the first display area DA1 and the second display area DA2. In an embodiment, the first demultiplexer circuits DMX1 may be arranged in the first demultiplexer area DMXA1 at a uniform pitch (e.g., the first pitch PIl of FIG. 10) along the second direction DR2.

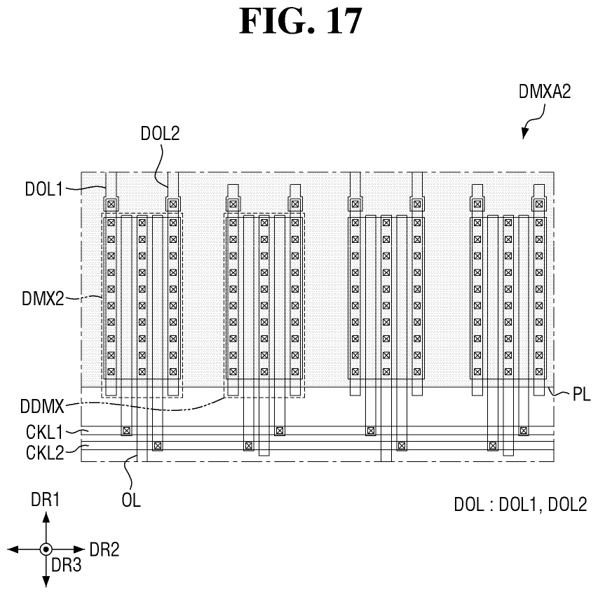

FIG. 17 is a plan view illustrating a second demultiplexer area DMXA2 according to an embodiment.

Referring to FIG. 17, second demultiplexer circuits DMX2 and dummy demultiplexer circuits DDMX may be positioned in the second demultiplexer area DMXA2. The second demultiplexer circuits DMX2 may be connected to the third data lines DL3 through respective data output lines DOL extending from the second demultiplexer area DMXA2. The dummy demultiplexer circuits DDMX may be disposed between the second demultiplexer circuits DMX2. For example, the second demultiplexer circuits DMX2 and the dummy demultiplexer circuits DDMX may be alternately arranged along the second direction DR2. In an embodiment, the second demultiplexer circuits DMX2 and the dummy demultiplexer circuits DDMX may be arranged in the second demultiplexer area DMXA2 at a uniform pitch (e.g., the first pitch PIl of FIG. 10) along the second direction DR2.

The dummy demultiplexer circuits DDMX may be separated from the driving circuit 200 and/or the third data lines DL3. For example, the dummy demultiplexer circuits DDMX may not be connected to the driving circuit 200 and the third data lines DL3, and ends of the dummy demultiplexer circuits DDMX may be floated or may be connected to lines supplying a constant voltage.

The dummy demultiplexer circuits DDMX are disposed between the second demultiplexer circuits DMX2 and, accordingly, the demultiplexer circuits DMX and the data output lines DOL may be disposed at substantially the same pitch as the pitch in the first demultiplexer area DMXA1 and/or the third demultiplexer area DMXA3 in the second demultiplexer area DMXA2. Accordingly, it is possible to form the data output lines DOL in a uniform direction and shape, and/or at uniform intervals and make loads of the output lines DOL and the demultiplexer units DMXU generally uniform. Accordingly, it is possible to prevent or reduce luminance deterioration and/or a luminance deviation of the pixels PX and improve image quality of the display device 10.

In concluding the detailed description, those skilled in the art will appreciate that many variations and modifications can be made to the embodiments without substantially departing from the principles of the present inventive concept. Therefore, the disclosed embodiments of the inventive concept are used in a generic and descriptive sense only and not for purposes of limitation.

What is claimed is:

1. A display device comprising:
a substrate including a main area and a sub-area protruding from one side of the main area in a first direction, the main area including a display area in which pixels are arranged and a non-display area surrounding the display area, and the sub-area including a demultiplexer area and a bending area positioned between the demultiplexer area and the main area; and
a circuit layer disposed on the substrate and including pixel circuits of the pixels arranged in the display area at a first pitch in a second direction crossing the first direction, data lines connected to the pixel circuits, and demultiplexer circuits arranged in the demultiplexer area at the first pitch in the second direction and including first switches and second switches,
wherein the circuit layer further includes:
first lines connected to the first switches, respectively, and second lines connected to the second switches, respectively, the first lines and the second lines extending from the demultiplexer area to the main area through the bending area and connecting the first switches and the second switches to the data lines, respectively; and
shield lines disposed between adjacent first lines and the second lines, respectively.

2. The display device of claim 1, wherein the first lines and the second lines are formed as straight lines extending in the first direction in the demultiplexer area, the bending area, and the main area.

3. The display device of claim 1, wherein the sub-area further includes a first line crossing area positioned between the demultiplexer area and the bending area, and a second line crossing area positioned between the bending area and the main area.

4. The display device of claim 3, wherein, in the demultiplexer area and the main area, the first lines and the second lines are arranged along the second direction in a first order, and
wherein, in the bending area, the first lines and the second lines are arranged along the second direction in a second order different from the first order, and
wherein the shield lines are disposed between adjacent first line groups each including at least two first lines and second line groups each including at least two second lines, respectively.

5. The display device of claim 4, wherein, in the first line crossing area, some of the first lines and some of the second lines cross each other, and
wherein, in the second line crossing area, the some of the first lines and the some of the second lines cross each other such that an arrangement order of the first lines and the second lines is the same as an arrangement order of the first lines and the second lines in the demultiplexer area.

6. The display device of claim 1, wherein the first lines, the second lines, and the shield lines are arranged at uniform intervals along the second direction in the bending area.

7. The display device of claim 1, wherein the first switches are turned on by a first clock signal and the second switches are turned on by a second clock signal.

8. The display device of claim 1, wherein the circuit layer further includes a power line positioned in the main area and the sub-area, and connected to the pixels, and
wherein the shield lines are connected to the power line around the bending area.

9. The display device of claim 8, wherein the circuit layer includes:
a semiconductor layer disposed on the substrate;
a first conductive layer disposed on a first insulating layer covering the semiconductor layer;
a second conductive layer disposed on a second insulating layer covering the first conductive layer;
a third conductive layer disposed on a third insulating layer covering the second conductive layer;
a fourth conductive layer disposed on a fourth insulating layer covering the third conductive layer; and
a fifth conductive layer disposed on a fifth insulating layer covering the fourth conductive layer.

10. The display device of claim 9, wherein the power line is provided at the fifth conductive layer in a first line crossing area positioned between the bending area and the demultiplexer area, and a second line crossing area positioned between the bending area and the main area.

11. The display device of claim 10, wherein the shield lines extend from the bending area to the first line crossing area and the second line crossing area, and
wherein each of the shield lines is provided at the fourth conductive layer in the bending area, and is provided at at least one of the first conductive layer, the second conductive layer, the third conductive layer, and the fourth conductive layer, and is electrically connected to the power line in the first line crossing area and the second line crossing area.

12. The display device of claim 10, wherein each of the shield lines is formed as a multilayer line including a first line layer provided at at least one of the first conductive layer, the second conductive layer, and the third conductive layer and a second line layer provided at the fourth conductive layer in the first line crossing area and the second line crossing area.

13. The display device of claim 10, wherein the first lines and the second lines are provided at at least one of the first conductive layer, the second conductive layer, the third conductive layer, and the fourth conductive layer in the demultiplexer area, the first line crossing area, the bending area, and the second line crossing area.

14. The display device of claim 1, wherein the display area includes:
a first display area which are positioned in an edge area of the display area in the second direction and in which first data lines and the pixels connected to the first data lines are arranged; and
a second display area which neighbors to the first display area in the second direction and overlaps a first demultiplexer area of the demultiplexer area in the first direction and in which second data lines and the pixels connected to the second data lines are arranged.

15. The display device of claim 14, wherein the demultiplexer circuits include first demultiplexer circuits positioned in the first demultiplexer area,
wherein some of the first lines and the second lines connected to the first demultiplexer circuits are connected to the second data lines, and
wherein the others of the first lines and the second lines connected to the first demultiplexer circuits are connected to the first data lines via connection lines passing through a boundary between the first display area and the second display area.

16. The display device of claim 15, wherein the first data lines extend in the first direction in the first display area,
wherein the second data lines extend in the first direction in the second display area, and
wherein the connection lines extend from the first display area to the second display area along the second direction.

17. The display area of claim 16, wherein the display area further includes a third display area which neighbors to the second display area in the second direction and overlaps a second demultiplexer area of the demultiplexer area in the first direction and in which third data lines and the pixels connected to the third data lines are arranged.

18. The display device of claim 17, wherein the demultiplexer circuits further includes:
second demultiplexer circuits positioned in the second demultiplexer area and connected to the third data lines through first lines and second lines extending from the second demultiplexer area; and
dummy demultiplexer circuits disposed between the second demultiplexer circuits.

19. The display device of claim 18, further comprising a driving circuit supplying data signals to the demultiplexer circuits,
wherein the dummy demultiplexer circuits are electrically disconnected to the driving circuit.

20. A display device comprising:
a substrate including a main area and a sub-area positioned on one side of the main area, the main area including a display area in which pixels are arranged, and the sub-area including a demultiplexer area and a first line crossing area, a bending area, and a second line crossing area sequentially disposed along a first direction between the demultiplexer area and the main area; and
a circuit layer disposed on the substrate and including data lines positioned in the display area and connected to the pixels, demultiplexer circuits positioned in the demultiplexer area and including first switches configured to receive a first clock signal and second switches configured to receive a second clock signal, and a power line positioned in the main area and the sub-area,
wherein the circuit layer further includes:
first lines connecting the first switches to corresponding data lines and second lines connecting the second switches to corresponding data lines; and
shield lines disposed between adjacent first lines and second lines, respectively, and connected to the power line, and
wherein the first lines and the second lines extend in the first direction in an area other than the first line crossing area and the second line crossing area.
